(19) United States
(12) Patent Application Publication
(10) Pub. No.: US 2026/0333872 A1
(43) Pub. Date: Oct. 22, 2026

(54) DISPLAY PANEL AND DISPLAY DEVICE

(71) Applicant: Beijing Visionox Technology Co., Ltd., Beijing (CN)

(72) Inventors: Enqing GUO, Beijing (CN); Cuili GAI, Beijing (CN); Jianjun LU, Beijing (CN); Xiaoyang JIN, Beijing (CN)

(73) Assignee: Beijing Visionox Technology Co., Ltd., Beijing (CN)

(21) Appl. No.: 19/700,413

(22) Filed: Jun. 8, 2026

(30) Foreign Application Priority Data
Jun. 19, 2025 (CN) 202510830162.6

(51) Int. Cl. H10D 86/40; H10D 86/60

(52) U.S. Cl. CPC H10D 86/441; H10D 86/421; H10D 86/60

(57) ABSTRACT

The present application discloses a display panel and a display device. The display panel includes a substrate; a first type active layer located on one side of the substrate; a second type active layer located on a side of the first type active layer away from the substrate; a first conductive layer located on a side of the first type active layer away from the substrate; a second conductive layer located on a side of the second type active layer away from the substrate; a gate signal line at least partially located in the first conductive layer and the second conductive layer, the gate signal line being used to transmit a same gate signal to the first transistor and the second transistor. The embodiment can reduce the space occupied by the pixel circuit, facilitate improving resolution, and thus facilitate optimizing the display effect.

### CROSS-REFERENCE TO RELATED APPLICATIONS

The present application claims priority to the Chinese Patent Application 202510830162.6, filed on Jun. 19, 2025, and the entire contents of the above application are hereby incorporated by reference in its entirety.

### FIELD

The present application relates to the field of display technology, and in particular, to a display panel and a display device.

### BACKGROUND

With the development of display technology, the requirements for display performance of display panels are increasingly higher.

Existing display panels suffer from poor display effects, failing to meet high-quality display demands.

### SUMMARY

The present application provides a display panel and a display device to improve display effects.

According to one aspect of the present disclosure, there is provided a display panel including: a substrate, a first type active layer, a second type active layer, a first transistor, a second transistor, a first conductive layer, a second conductive layer and a gate signal line;

The first type active layer is located on one side of the substrate. The second type active layer is located on a side of the first type active layer away from the substrate. A channel region of the first transistor is located in the first type active layer. A channel region of the second transistor is located in the second type active layer. The first conductive layer is located on a side of the first type active layer away from the substrate. The second conductive layer is located on a side of the second type active layer away from the substrate. The gate signal line is at least partially located in the first conductive layer and the second conductive layer. The gate signal line is configured to transmit a same gate signal to the first transistor and the second transistor.

In an embodiment, the first type active layer includes a first active region, and the second type active layer includes a second active region. In a direction perpendicular to the substrate, a position where the same gate signal line overlaps the first active region forms a gate of the first transistor, and a position where it overlaps the second active region forms a gate of the second transistor.

The display panel includes a plurality of rows of pixel circuits arranged sequentially. The first transistor is located in any one row of pixel circuits, and the second transistor is located in an adjacent row of pixel circuits to the row where the first transistor is located.

In a direction perpendicular to the substrate, a position where the same gate signal line overlaps the first active region forms a gate of the first transistor of a current row of pixel circuits, and a position where it overlaps the second active region forms a gate of the second transistor of a next row of pixel circuits.

The first active region and the second active region extend along a first direction, and orthographic projections of the first active region and the second active region on the substrate are arranged along a second direction. The first transistor is configured to transmit a first power signal to a driving transistor of the corresponding pixel circuit, the first transistor and the driving transistor are disposed within one pixel circuit. The second transistor is configured to transmit a first initialization signal to a light-emitting element connected to the corresponding pixel circuit.

In an embodiment, the display panel further includes a driving transistor. A channel region of the driving transistor is located in the second type active layer. Orthographic projections of the channel region of the first transistor and the channel region of the second transistor in the same pixel circuit on the substrate are located on different sides of an orthographic projection of the channel region of the driving transistor on the substrate.

In an embodiment, the gate signal line includes a first gate signal line and a second gate signal line. The first gate signal line is located in the first conductive layer, and a position where the first gate signal line overlaps the first active region forms a gate of the first transistor of a current row of pixel circuits. The second gate signal line is located in the second conductive layer, and a position where the second gate signal line overlaps the second active region forms a gate of the second transistor of a next row of pixel circuits.

In an embodiment, the first type active layer includes a first active region, and the second type active layer includes a second active region.

In a direction perpendicular to the substrate, a position where the same gate signal line overlaps the first active region forms a gate of the first transistor, and a position where it overlaps the second active region forms a gate of the second transistor. The first transistor and the second transistor are located in the same pixel circuit.

The display panel further includes a driving transistor, the first active region extends along a second direction, and the second active region extends along a first direction. The first transistor is configured to transmit a second initialization signal to the driving transistor of the pixel circuit, and the second transistor is configured to transmit a data signal to the driving transistor of the pixel circuit, with the first transistor and the second transistor being located in the same pixel circuit.

Or the first active region extends along a first direction, and the second active region extends along a second direction. The first transistor is configured to transmit a data signal to the driving transistor of a current row of pixel circuits, and the second transistor is configured to transmit a second initialization signal to the driving transistor of the current row of pixel circuits.

In an embodiment, the channel region of the driving transistor is located in the second type active layer. The orthographic projections of the channel region of the first transistor and the channel region of the second transistor in the same pixel circuit on the substrate are on the same side as the orthographic projection of the channel region of the driving transistor on the substrate.

In an embodiment, the gate signal line includes a first gate signal line and a second gate signal line. The first gate signal line is located in the first conductive layer, and the overlapping position of the first gate signal line and the first active region forms the gate of the first transistor. The second gate signal line is located in the second conductive layer, and the overlapping position of the second gate signal line and the second active region forms the gate of the second transistor.

In an embodiment, the first type active layer includes a first active region, and the second type active layer includes a second active region. In a direction perpendicular to the substrate, the overlapping positions of the same gate signal line with the first active region and the second active region form the gate of the first transistor and the gate of the second transistor of the same pixel circuit.

The first active region and the second active region extend along a first direction, and the orthographic projections of the first active region and the second active region on the substrate are arranged along a second direction. The first transistor is used to transmit a first power signal to the driving transistor of the pixel circuit, and the second transistor is used to transmit a first initialization signal to the light-emitting element connected to the pixel circuit. The first transistor and the second transistor are located in the same pixel circuit.

In an embodiment, the display panel further includes a driving transistor, and the channel region of the driving transistor is located in the second active layer. The orthographic projections of the channel region of the first transistor and the channel region of the second transistor in the same pixel circuit on the substrate are on the same side as the orthographic projection of the channel region of the driving transistor on the substrate.

In an embodiment, the gate signal line includes a first gate signal line and a second gate signal line. The first gate signal line is located in the first conductive layer, and the overlapping position of the first gate signal line and the first active region forms the gate of the first transistor of the current row pixel circuit. The second gate signal line is located in the second conductive layer, and the overlapping position of the second gate signal line and the second active region forms the gate of the second transistor of the current row pixel circuit.

In an embodiment, the display panel further includes a first auxiliary signal line. The first auxiliary signal line is arranged in a different layer from the first gate signal line and the second gate signal line. The first gate signal line is connected to the second gate signal line through the first auxiliary signal line.

In an embodiment, the first gate signal line is connected to the first auxiliary signal line through a first type via, and the second gate signal line is connected to the first auxiliary signal line through a second type via.

In an embodiment, the display panel further includes a third conductive layer, and the third conductive layer is located on a side of the second conductive layer away from the substrate. The first auxiliary signal line is located in the third conductive layer.

In an embodiment, the orthographic projection of the first gate signal line on the substrate, the orthographic projection of the second gate signal line on the substrate, and the orthographic projection of the first auxiliary signal line on the substrate at least partially overlap.

In an embodiment, the display panel further includes a first initialization signal line and a third conductive layer. The third conductive layer is located on a side of the second conductive layer away from the substrate. The first initialization signal line is located in the third conductive layer. The first initialization signal line is connected to the first electrode of the second transistor through a second type via, and the second electrode of the second transistor is connected to the first electrode layer of the light-emitting element.

In an embodiment, in the same pixel circuit, the orthographic projection of the first gate of the driving transistor on the substrate is located between the orthographic projection of the first initialization signal line on the substrate and the orthographic projection of the first gate signal line on the substrate.

In an embodiment, the orthographic projection of the first initialization signal line of the current row pixel circuit on the substrate is located on a side of the orthographic projection of the first gate signal line of the previous row pixel circuit on the substrate away from the orthographic projection of the first gate of the driving transistor of the current row pixel circuit on the substrate.

In an embodiment, the first gate of the driving transistor is located in the second conductive layer.

In an embodiment, the display panel further includes a fourth conductive layer, and the fourth conductive layer is located between the first conductive layer and the second type active layer.

The pixel circuit further includes a first capacitor, and the first capacitor includes a first plate and a second plate arranged in a stack. The first plate is located in the first conductive layer, and the second plate is located in the fourth conductive layer. The first gate of the driving transistor is connected to the first plate through a first connection line, and the second plate is connected to the first electrode layer of the light-emitting element through a second connection line.

In an embodiment, the first gate of the driving transistor is connected to one end of the first connection line through a second type via. The first plate is connected to the other end of the first connection line through a first type via, and the second plate is connected to the second connection line through a first type via.

In an embodiment, the second gate of the driving transistor is located in the fourth conductive layer. The orthographic projection of the second plate on the substrate overlaps with the orthographic projection of the channel region of the driving transistor on the substrate. The second plate is reused as the second gate of the driving transistor.

In an embodiment, the orthographic projection of the second plate on the substrate at least partially covers the orthographic projection of the first gate of the driving transistor on the substrate.

In an embodiment, the second type active layer further includes a third active region, the third active region extends along the first direction, and the third active region is arranged in the same layer as the second active region and spaced apart. The pixel circuit further includes a third transistor, and the channel region of the third transistor is located in the third active region. The gate of the third transistor is located in the second conductive layer, the first electrode of the third transistor is connected to the first electrode of the driving transistor, and the second electrode of the third transistor is connected to the first gate of the driving transistor through a third connection line.

In an embodiment, the second electrode of the third transistor is connected to one end of the third connection line through a second type via, and the first gate of the driving transistor is connected to the other end of the third connection line through a second type via.

In an embodiment, the third connection line and the first connection line are of an integral structure.

In an embodiment, the channel region of the third transistor is located at the overlapping position of the orthographic projection of the gate of the third transistor on the third active region.

In an embodiment, the display panel further includes a third gate signal line, and the third gate signal line is connected to the gate of the third transistor through a second type via.

In an embodiment, the orthographic projection of the third gate signal line on the substrate at least partially overlaps with the orthographic projection of the gate of the third transistor on the substrate.

In an embodiment, in the same row of pixel circuits extending along the second direction, the orthographic projection of the third gate signal line on the substrate is located between the orthographic projection of the first gate signal line on the substrate and the orthographic projection of the first gate of the driving transistor on the substrate.

In an embodiment, the display panel further includes a fourth conductive layer, the fourth conductive layer is located between the first conductive layer and the second type active layer. The pixel circuit further includes a first capacitor. The first capacitor includes a first plate and a second plate arranged in a stack. The first plate is located in the first conductive layer, and the second plate is located in the fourth conductive layer. The second gate of the driving transistor is connected to the second plate, and the first gate of the driving transistor is connected to the second electrode of the driving transistor via a fourth connection line.

In an embodiment, the second gate of the driving transistor is located in the fourth conductive layer, and the second plate is reused as the second gate of the driving transistor. In one embodiment, the first gate of the driving transistor is located in the second conductive layer.

In an embodiment, the first gate of the driving transistor is connected to one end of the fourth connection line via a second type via hole, and the second electrode of the driving transistor is connected to the other end of the fourth connection line via a second type via hole. The first plate is connected to the first electrode layer of the light-emitting element via a second connection line.

In an embodiment, the orthographic projection of the first plate on the substrate at least partially overlaps with the orthographic projection of the second gate of the driving transistor on the substrate, and the orthographic projection of the second gate of the driving transistor on the substrate at least partially overlaps with the orthographic projection of the first gate of the driving transistor on the substrate.

In an embodiment, the display panel further includes a first initialization signal line and a third conductive layer. The first initialization signal line is located in the third conductive layer, and the first initialization signal line is connected to the first electrode of the second transistor via a second type via hole. The second electrode of the second transistor is connected to the first plate via a fifth connection line.

In an embodiment, the second electrode of the second transistor is connected to one end of the fifth connection line via a second type via hole. The first plate is connected to the other end of the fifth connection line via a first type via hole.

In an embodiment, in the same row of pixel circuits extending along the second direction, the orthographic projection of the first initialization signal line on the substrate is located on a side of the orthographic projection of the first gate signal line on the substrate away from the orthographic projection of the first gate of the driving transistor on the substrate.

In an embodiment, the second type active layer further includes a third active region, the third active region extends along the first direction, and the third active region is in the same layer as the second active region and is not connected. The pixel circuit further includes a third transistor. A channel region of the third transistor is located in the third active region, a gate of the third transistor is located in the second conductive layer, a first electrode of the third transistor is connected to the first electrode of the driving transistor, and a second electrode of the third transistor is connected to the second gate of the driving transistor via a third connection line.

In an embodiment, the channel region of the third transistor is spaced apart from the channel region of the driving transistor.

In an embodiment, the second electrode of the third transistor is connected to one end of the third connection line via a second type via hole. The second gate of the driving transistor is connected to the other end of the third connection line via a second type via hole.

In an embodiment, the channel region of the third transistor is located at a position where the orthographic projection of the gate of the third transistor on the third active region overlaps.

In an embodiment, the display panel further includes a third gate signal line, the third gate signal line is connected to the gate of the third transistor via a second type via hole. In one embodiment, the orthographic projection of the third gate signal line on the substrate at least partially overlaps with the orthographic projection of the gate of the third transistor on the substrate.

In an embodiment, in the same row of pixel circuits extending along the second direction, the orthographic projection of the third gate signal line on the substrate is located between the orthographic projection of the first gate signal line on the substrate and the orthographic projection of the second gate of the driving transistor on the substrate.

In an embodiment, the third gate signal line extends along the second direction, and the orthographic projection of the third gate signal line on the substrate overlaps with the orthographic projection of the first plate on the substrate.

In an embodiment, the display panel further includes a power line and a fifth conductive layer, the fifth conductive layer is located on a side of the third conductive layer away from the substrate, and the power line is located in the fifth conductive layer. The first electrode of the first transistor is connected to the power line via a sixth connection line, and the second electrode of the first transistor is connected to the first electrode of the driving transistor via a seventh connection line.

In an embodiment, the first electrode of the first transistor is connected to one end of the sixth connection line via a first type via hole. The power line is connected to the other end of the sixth connection line via a third type via hole. The second electrode of the first transistor is connected to one end of the seventh connection line via a first type via hole, and the first electrode of the driving transistor is connected to the other end of the seventh connection line via a second type via hole.

In an embodiment, the orthographic projection of the third gate signal line on the substrate overlaps with the orthographic projection of the first active region on the substrate.

In an embodiment, the second type active layer further includes a fourth active region. The fourth active region includes a first branch portion extending along the first direction, a second branch portion extending along the second direction, and a third branch portion extending along the first direction. The channel region of the driving transistor is located in the second branch portion, and the orthographic projection of the first gate of the driving transistor on the substrate at least overlaps with the orthographic projection of the second branch portion on the substrate.

In an embodiment, the first electrode of the third transistor is connected to the first electrode of the driving transistor via the third branch portion.

In an embodiment, the third active region and the fourth active region are connected as an integral structure.

In an embodiment, the pixel circuit further includes a second capacitor, the second capacitor includes a third plate and a fourth plate arranged in a stack. The third plate is located in the first conductive layer, the fourth plate is located in the fourth conductive layer, and the fourth plate is connected to the first electrode of the driving transistor via an eighth connection line.

In an embodiment, the fourth plate is connected to one end of the eighth connection line via a first type via hole. The first electrode of the driving transistor is connected to the other end of the eighth connection line via a second type via hole.

In an embodiment, the orthographic projection of the third plate on the substrate covers the orthographic projection of the fourth plate on the substrate.

In an embodiment, the orthographic projection of the third plate on the substrate is located on a side of the orthographic projection of the first gate of the driving transistor on the substrate away from the orthographic projection of the third gate signal line on the substrate.

In an embodiment, the pixel circuit further includes a fourth transistor and a fifth transistor. The first-type active layer further includes a fifth active region. The second-type active layer further includes a sixth active region. A channel region of the fourth transistor is located in the sixth active region, and a channel region of the fifth transistor is located in the fifth active region.

In an embodiment, the display panel further includes a data line, a second initialization signal line, and a fifth conductive layer. The fifth conductive layer is located on a side of the third conductive layer away from the substrate. The data line is located in the fifth conductive layer, and the second initialization signal line is located in the third conductive layer. A first electrode of the fourth transistor is connected to the data line via a ninth connection line. A second electrode of the fourth transistor is connected to the third electrode plate via a tenth connection line. A first electrode of the fifth transistor is connected to the second initialization signal line. A second electrode of the fifth transistor is connected to the tenth connection line.

In an embodiment, the first electrode of the fourth transistor is connected to one end of the ninth connection line via a second-type via hole. The data line is connected to the other end of the ninth connection line via a third-type via hole. The second electrode of the fourth transistor is connected to one end of the tenth connection line via a second-type via hole. The third electrode plate is connected to the other end of the tenth connection line via a first-type via hole.

In an embodiment, the first electrode of the fifth transistor is connected to the second initialization signal line via a first-type via hole, and the second electrode of the fifth transistor is connected to the tenth connection line via a first-type via hole.

In an embodiment, the display panel further includes a fourth gate signal line and a fifth gate signal line. The channel region of the fourth transistor is located at an overlapping position of an orthographic projection of the fifth gate signal line on the sixth active region. The channel region of the fifth transistor is located at an overlapping position of an orthographic projection of the fourth gate signal line on the fifth active region.

In an embodiment, the orthographic projection of the fourth gate signal line on the substrate at least partially overlaps with the orthographic projection of the fifth gate signal line on the substrate.

In an embodiment, the fourth gate signal line and the fifth gate signal line transmit the same signal.

In an embodiment, the fifth gate signal line includes a main body portion and a branch portion, and the channel region of the fourth transistor is located at a position where the branch portion of the fifth gate signal line overlaps with the sixth active layer.

In an embodiment, the main body portions of the fourth gate signal line and the fifth gate signal line both extend along a second direction. The branch portion of the fifth gate signal line extends along a first direction, and the first direction intersects the second direction.

In an embodiment, the fifth active region extends along the first direction, and the sixth active region extends along the second direction.

In an embodiment, the orthographic projection of the main body portion of the fifth gate signal line on the substrate overlaps with the orthographic projection of the fourth gate signal line on the substrate.

In an embodiment, the orthographic projection of the fourth gate signal line on the substrate is located on a side of the orthographic projection of the third electrode plate on the substrate away from the orthographic projection of the first gate of the driving transistor on the substrate.

In an embodiment, the orthographic projection of the third gate signal line on the substrate and the orthographic projection of the fourth gate signal line on the substrate are respectively located on different sides of the orthographic projection of the first gate of the driving transistor on the substrate.

In an embodiment, the display panel further includes a second auxiliary signal line. The second auxiliary signal line is disposed in a different layer from the fourth gate signal line and the fifth gate signal line. The fourth gate signal line is connected to the fifth gate signal line via the second auxiliary signal line.

In an embodiment, the fourth gate signal line is located in a first conductive layer, and the fifth gate signal line is located in a second conductive layer. The second auxiliary signal line is located in a third conductive layer. The fourth gate signal line is connected to the second auxiliary signal line via a first-type via hole, and the fifth gate signal line is connected to the second auxiliary signal line via a second-type via hole.

In an embodiment, the pixel circuit further includes a sixth transistor. The first-type active layer further includes a seventh active region, the seventh active region extends along the first direction, and the seventh active region is in the same layer as and not connected to the fifth active region. A channel region of the sixth transistor is located in the seventh active region, a first electrode of the sixth transistor is connected to the second electrode of the driving transistor via an eleventh connection line, and a second electrode of the sixth transistor is connected to the first electrode layer of the light-emitting element via a twelfth connection line.

In an embodiment, the channel region of the sixth transistor is located at an overlapping position of the orthographic projection of the fourth gate signal line on the seventh active region.

In an embodiment, the first electrode of the sixth transistor is connected to one end of the eleventh connection line via a first-type via hole, and the second electrode of the driving transistor is connected to the other end of the eleventh connection line via a second-type via hole. The second electrode of the sixth transistor is connected to the twelfth connection line via a first-type via hole.

In an embodiment, the pixel circuit further includes a fourth transistor and a fifth transistor. The first-type active layer further includes a fifth active region. The second-type active layer further includes a sixth active region. A channel region of the fourth transistor is located in the fifth active region, and a channel region of the fifth transistor is located in the sixth active region. In one embodiment, the display panel further includes a data line, a second initialization signal line, and a fifth conductive layer. The fifth conductive layer is located on a side of the third conductive layer away from the substrate, and the data line is located in the fifth conductive layer. The second initialization signal line is located in the third conductive layer. A first electrode of the fourth transistor is connected to the data line via a ninth connection line, and a second electrode of the fourth transistor is connected to the third electrode plate via a tenth connection line. A first electrode of the fifth transistor is connected to the second initialization signal line, and a second electrode of the fifth transistor is connected to the tenth connection line.

In an embodiment, the first electrode of the fourth transistor is connected to one end of the ninth connection line via a first-type via hole, and the data line is connected to the other end of the ninth connection line via a third-type via hole. The second electrode of the fourth transistor is connected to one end of the tenth connection line via a first-type via hole, and the third electrode plate is connected to the other end of the tenth connection line via a first-type via hole.

In an embodiment, the first electrode of the fifth transistor is connected to the second initialization signal line via a second-type via hole, and the second electrode of the fifth transistor is connected to the tenth connection line via a second-type via hole.

In an embodiment, the display panel further includes a fourth gate signal line and a fifth gate signal line. The channel region of the fourth transistor is located at a position of an orthographic projection of the fourth gate signal line on the fifth active region. The channel region of the fifth transistor is located at a position of an orthographic projection of the fifth gate signal line on the sixth active region.

In an embodiment, the orthographic projection of the fourth gate signal line on the substrate at least partially overlaps with the orthographic projection of the fifth gate signal line on the substrate.

In an embodiment, the fourth gate signal line and the fifth gate signal line transmit the same signal.

In an embodiment, the fourth gate signal line includes a main body portion and a branch portion, and the channel region of the fourth transistor is located at a position where the branch portion of the fourth gate signal line overlaps the fifth active region.

In an embodiment, both the fifth gate signal line and the main body portion of the fourth gate signal line extend along a second direction, and the branch portion of the fourth gate signal line extends along a first direction, the first direction intersecting the second direction. In one embodiment, the sixth active region extends along the first direction, and the fifth active region extends along the second direction.

In an embodiment, an orthographic projection of the main body portion of the fourth gate signal line on the substrate overlaps an orthographic projection of the fifth gate signal line on the substrate.

In an embodiment, an orthographic projection of the fourth gate signal line on the substrate is located on a side of an orthographic projection of the third electrode plate on the substrate away from an orthographic projection of the first gate of the driving transistor on the substrate.

In an embodiment, an orthographic projection of the third gate signal line on the substrate and an orthographic projection of the fourth gate signal line on the substrate are located on different sides of the orthographic projection of the first gate of the driving transistor on the substrate.

In an embodiment, the display panel further includes a second auxiliary signal line, the second auxiliary signal line being disposed in a different layer from the fourth gate signal line and the fifth gate signal line. The fourth gate signal line is connected to the fifth gate signal line via the second auxiliary signal line.

In an embodiment, the fourth gate signal line is located in a first conductive layer. The fifth gate signal line is located in a second conductive layer. The second auxiliary signal line is located in a third conductive layer. The fourth gate signal line is connected to the second auxiliary signal line via a first type via, and the fifth gate signal line is connected to the second auxiliary signal line via a second type via.

In an embodiment, the pixel circuit further includes a sixth transistor, a channel region of the sixth transistor being located in a fourth active region. A first electrode of the sixth transistor is connected to a second electrode of the driving transistor via the fourth active region, and a second electrode of the sixth transistor is connected to a first electrode layer of a light-emitting element via a twelfth connection line.

In an embodiment, the channel region of the sixth transistor is located at a position where an orthographic projection of the fifth gate signal line overlaps the fourth active region.

In an embodiment, the second electrode of the sixth transistor is connected to one end of the twelfth connection line via a second type via, and the first electrode layer of the light-emitting element is connected to the other end of the twelfth connection line.

In an embodiment, the display panel further includes a power line, a data line, a first electrode line, and a first electrode layer, the power line, the data line, and the first electrode line all extending along the first direction. The display panel further includes a fourth conductive layer and a fifth conductive layer, the fourth conductive layer being located between the first conductive layer and a second type active layer. The fifth conductive layer is located on a side of the third conductive layer away from the substrate. The power line, the data line, and the first electrode line are located in the fifth conductive layer. The first electrode layer is located on a side of the fifth conductive layer away from the substrate.

In an embodiment, the first electrode layer is connected to the first electrode line via a fourth type via.

In an embodiment, an orthographic projection of the data line on the substrate is located on a side of an orthographic projection of the power line on the substrate away from an orthographic projection of the first gate of the driving transistor on the substrate.

In an embodiment, an orthographic projection of the data line on the substrate is located on a side of an orthographic projection of the power line on the substrate away from an orthographic projection of the first electrode line on the substrate.

In an embodiment, the display panel includes a plurality of pixel circuits, each of the pixel circuits includes a plurality of transistors, an orthographic projection of the power line on the substrate at least covers an orthographic projection of channel regions of part of the transistors in each of the pixel circuit.

In an embodiment, an orthographic projection of the first electrode layer on the substrate at least covers an orthographic projection of channel regions of part of the transistors on the substrate.

In an embodiment, the display panel further includes a first insulating layer, a second insulating layer, a third insulating layer, a fourth insulating layer, a fifth insulating layer, a sixth insulating layer, and a seventh insulating layer. The first insulating layer is located between the first type active layer and the first conductive layer. The second insulating layer is located between the first conductive layer and the fourth conductive layer. The third insulating layer is located between the fourth conductive layer and the second type active layer. The fourth insulating layer is located between the second type active layer and the second conductive layer. The fifth insulating layer is located between the second conductive layer and the third conductive layer. The sixth insulating layer is located between the third conductive layer and the fifth conductive layer. The seventh insulating layer is located between the fifth conductive layer and the first electrode layer. The display panel includes a first type via, a second type via, a third type via, and a fourth type via. In one embodiment, the first type via penetrates the fifth insulating layer, the fourth insulating layer, and the third insulating layer, or the first type via penetrates the fifth insulating layer, the fourth insulating layer, the third insulating layer, and the second insulating layer, or the first type via penetrates the fifth insulating layer, the fourth insulating layer, the third insulating layer, the second insulating layer, and the first insulating layer. The second type via penetrates the fifth insulating layer, or the second type via penetrates the fifth insulating layer and the fourth insulating layer; the third type via penetrates the sixth insulating layer, and the fourth type via penetrates the seventh insulating layer.

In an embodiment, the display panel further includes a spare signal line, the spare signal line being located in the fifth conductive layer, the spare signal line extending along the first direction, and along the second direction, M pixel circuits are spaced between adjacent spare signal lines, the first direction intersecting the second direction, M being an integer greater than or equal to 2 and less than or equal to 12.

In an embodiment, an orthographic projection of a connection hole between the first gate signal line, the second gate signal line, and the first auxiliary signal line on the substrate at least partially overlaps an orthographic projection of the spare signal line on the substrate.

According to another aspect of the present application, a display device is provided, including the display panel provided by any embodiment of the present application. The embodiments of the present disclosure, by arranging gate signal lines that provide the same gate signal for the first transistor and the second transistor of different channel types in different conductive layers of a stack, can flexibly select to connect their gates from different directions and heights, thereby avoiding complex wiring for connecting different types of transistors in the same plane. Furthermore, distributing the gate signal lines transmitting the same gate signal into different conductive layers can reduce the number of wirings in a single conductive layer, reduce the complexity of wiring, thereby reducing the space occupied by the signal lines, which is beneficial for improving resolution, and further beneficial for optimizing the display effect.

The content described in this section is not intended to identify key or important features of embodiments of the present disclosure, nor is it intended to limit the scope of the present disclosure. Other features of the present disclosure will become readily understood from the following description.

### BRIEF DESCRIPTION OF THE DRAWINGS

To clearly illustrate the embodiments, the drawings required for description are introduced below. The drawings depict some embodiments, and other drawings can be derived in the art without undue experimentation.

FIG. 1 is a schematic plan view of a display panel provided by an embodiment of the present application;

FIG. 2 is a schematic cross-sectional view of a display panel provided by an embodiment of the present application;

FIG. 3 is a schematic plan view of another display panel provided by an embodiment of the present application;

FIG. 4 is a schematic structural view of a pixel circuit provided by an embodiment of the present application;

FIG. 5 is a schematic plan view of another display panel provided by an embodiment of the present application;

FIG. 6 is a schematic cross-sectional view of another display panel provided by an embodiment of the present application;

FIG. 7 is a schematic plan view of another display panel provided by an embodiment of the present application;

FIG. 8 is a schematic cross-sectional view of another display panel provided by an embodiment of the present application;

FIG. 9 is a schematic plan view of another display panel provided by an embodiment of the present application;

FIG. 10 is a schematic cross-sectional view of another display panel provided by an embodiment of the present application;

FIG. 11 is a schematic plan view of another display panel provided by an embodiment of the present application;

FIG. 12 is a schematic structural view of a fourth active region provided by an embodiment of the present application;

FIG. 13 is a schematic plan view of another display panel provided by an embodiment of the present application;

FIG. 14 is a schematic cross-sectional view of another display panel provided by an embodiment of the present application;

FIG. 15 is a schematic plan view of another display panel provided by an embodiment of the present application;

FIG. 16 is a schematic cross-sectional view of another display panel provided by an embodiment of the present application;

FIG. 17 is a schematic plan view of another display panel provided by an embodiment of the present application;

FIG. 18 is a schematic plan view of another display panel provided by an embodiment of the present application;

FIG. 19 is a schematic cross-sectional view of another display panel provided by an embodiment of the present application;

FIG. 20 is a schematic plan view of another display panel provided by an embodiment of the present application;

FIG. 21 is a schematic structural view of another pixel circuit provided by an embodiment of the present application;

FIG. 22 is a schematic plan view of another display panel provided by an embodiment of the present application;

FIG. 23 is a schematic plan view of another display panel provided by an embodiment of the present application;

FIG. 24 is a schematic structural view of another pixel circuit provided by an embodiment of the present application;

FIG. 25 is a schematic plan view of another display panel provided by an embodiment of the present application;

FIG. 26 is a schematic plan view of another display panel provided by an embodiment of the present application;

FIG. 27 is a schematic structural view of a display device provided by an embodiment of the present application.

### DETAILED DESCRIPTION

To enable a better understanding of the solutions of the present disclosure, the embodiments of the present disclosure will be clearly and completely described below in conjunction with the drawings in the embodiments of the present disclosure. In one embodiment, the described embodiments are only a part of the embodiments of the present disclosure, rather than all of the embodiments.

The terms “first”, “second”, etc. in the description and claims of the present disclosure and the above drawings are used to distinguish similar objects, and are not necessarily used to describe a specific order or sequence. The data used can be interchanged where appropriate, and the embodiments of the present disclosure described herein can be implemented in an order other than those illustrated or described herein. Furthermore, the terms “comprising” and “having” and any variations thereof are intended to cover non-exclusive inclusion, for example, a process, method, system, product, or device including a series of steps or units is not necessarily limited to those steps or units explicitly listed, but may include other steps or units not explicitly listed or inherent to such process, method, product, or device.

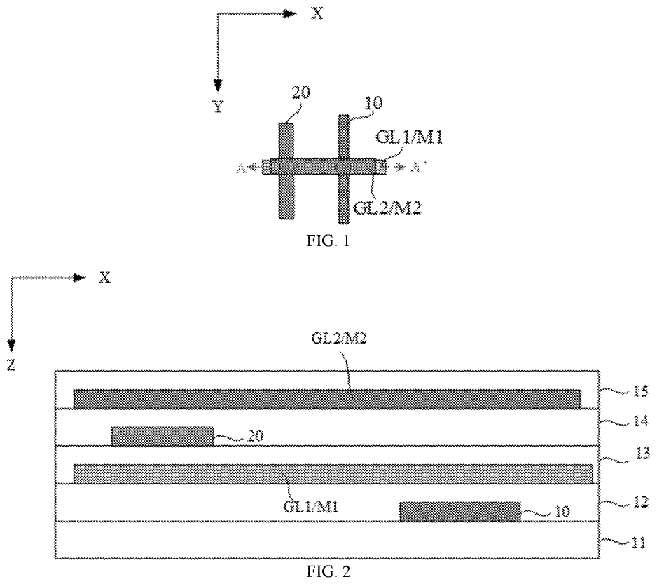

FIG. 1 is a schematic plan view of a display panel provided by an embodiment of the present disclosure, and FIG. 2 is a schematic cross-sectional view of a display panel provided by an embodiment of the present disclosure, and FIG. 1 only shows a portion of the structure of the display panel, and FIG. 2 is, in one embodiment, a cross-sectional structure taken along section line AA′ of FIG. 1. Referring to FIGS. 1 and 2, the display panel provided in this embodiment includes: a substrate 11, a first type active layer 10, a second type active layer 20, a first transistor Q1, a second transistor Q2, a first conductive layer M1, a second conductive layer M2, and a gate signal line. The first type active layer 10 is located on one side of the substrate 11. The second type active layer 20 is located on a side of the first type active layer 10 away from the substrate 11.

The channel region of the first transistor Q1 is located in the first type active layer 10.

The channel region of the second transistor Q2 is located in the second type active layer 20;

The first conductive layer M1 is located on a side of the first type active layer 10 away from the substrate 11.

The second conductive layer M2 is located on a side of the second type active layer 20 away from the substrate 11.

At least a portion of the gate signal line is located in the first conductive layer M1 and the second conductive layer M2, and the gate signal line is used to transmit a same gate signal to the first transistor Q1 and the second transistor Q2.

In one embodiment, the substrate 11 is used to provide protection and support for the display panel, and the substrate 11 can be a flexible base formed of materials such as polyimide (PI), polyethylene naphthalate (PEN), or polyethylene terephthalate (PET), or can be a rigid base formed of materials such as glass. On one side of the substrate 11, multiple conductive layers are disposed, and the multiple conductive layers are isolated from each other by insulating layers.

The first-type active layer 10 and the second-type active layer 20 are different. For example, one of the first-type active layer 10 and the second-type active layer 20 is a polysilicon active layer, and the other is a metal oxide active layer. The channel regions of the first transistor Q1 and the second transistor Q2 are respectively located in different active layers. In this embodiment, the first-type active layer 10 is a low-temperature polysilicon active layer, and the second-type active layer 20 is a metal oxide semiconductor active layer.

In this embodiment, at least a portion of a gate signal line for transmitting the same gate signal to the first transistor Q1 and the second transistor Q2 is located in the first conductive layer M1 and the second conductive layer M2, that is, the same gate signal line is distributed in different stacked conductive layers to provide the same gate signal to different types of transistors. For example, the gate signal line includes a first gate signal line GL1 located in the first conductive layer M1 and a second gate signal line GL2 located in the second conductive layer M2, the first gate signal line GL1 provides a gate signal to the first transistor Q1, and the second gate signal line GL2 provides a gate signal to the second transistor Q2. Since the types of the first transistor Q1 and the second transistor Q2 are different, by distributing the gate signal line in different conductive layers, the gates of the two transistors can be flexibly connected from different directions and heights according to their specific positions, orientations, and connection relationships with other circuit elements.

For example, the first transistor Q1 may be more suitable for receiving the gate signal from the upper conductive layer, while the second transistor Q2 can receive the signal from the lower conductive layer, thereby making the connection lines shorter and more direct, avoiding complex wiring in the same plane to connect different types of transistors, thus saving pixel circuit space. The embodiments of the present disclosure, by arranging the gate signal line providing the same gate signal to the first transistor Q1 and the second transistor Q2 of different channel types in different stacked conductive layers, can flexibly select different directions and heights to connect the gates of the two transistors, thereby avoiding complex wiring in the same plane to connect different types of transistors.

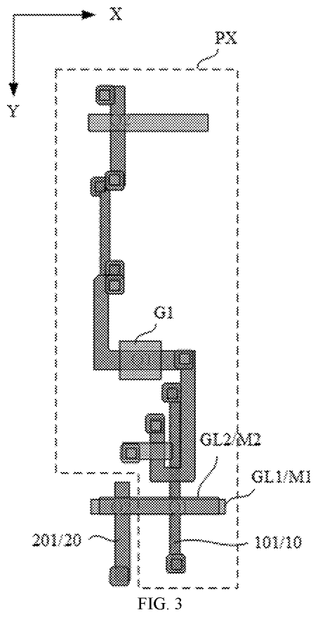

Furthermore, distributing the gate signal line transmitting the same gate signal into different conductive layers can reduce the number of wirings in a single conductive layer, reduce wiring complexity, thereby reducing the space occupied by the pixel circuit, which is beneficial for improving resolution and thus optimizing display effects. FIG. 3 is a schematic plan view of another display panel provided by an embodiment of the present disclosure.

Referring to FIG. 3, based on the above embodiments, in one embodiment, the first-type active layer 10 includes a first active region 101, and the second-type active layer 20 includes a second active region 201. In a direction perpendicular to the substrate 11 (Z direction), the overlapping position of the same gate signal line with the first active region 101 forms the gate of the first transistor Q1 of the current row pixel circuit PX, and the overlapping position with the second active region 201 forms the gate of the second transistor Q2 of the next row pixel circuit PX. The gate signal line includes a first gate signal line GL1 and a second gate signal line GL2. The first gate signal line GL1 is located in the first conductive layer M1, and the overlapping position of the first gate signal line GL1 with the first active region 101 forms the gate of the first transistor Q1 of the current row pixel circuit PX. The second gate signal line GL2 is located in the second conductive layer M2, and the overlapping position of the second gate signal line GL2 with the second active region 201 forms the gate of the second transistor Q2 of the next row pixel circuit PX. That is, the gate driving of the first transistor Q1 of the current row pixel circuit PX and the gate driving of the second transistor Q2 of the next row pixel circuit PX are performed simultaneously.

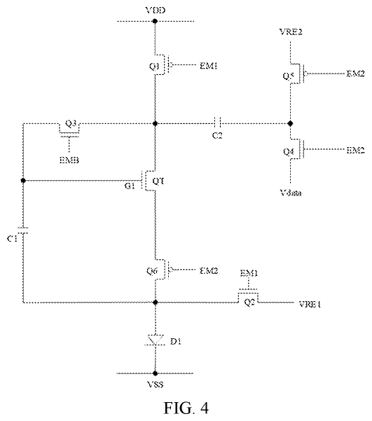

FIG. 4 is a schematic structural diagram of a pixel circuit provided by an embodiment of the present disclosure. Referring to FIGS. 3 and 4, the first active region 101 and the second active region 201 extend along a first direction Y, and the orthographic projections of the first active region 101 and the second active region 201 on the substrate 11 are arranged along a second direction X. The display panel further includes a driving transistor QT, the first transistor Q1 is used to transmit a first power signal VDD to the driving transistor QT of the current row pixel circuit PX, and the second transistor Q2 is used to transmit a first initialization signal VRE1 to a light-emitting element connected to the next row pixel circuit PX. In one embodiment, the first direction Y is the column direction in which the pixel circuits PX are arranged, and the second direction X is the row direction. In one embodiment, the first transistor Q1 is a P-type transistor, the second transistor Q2 is an N-type transistor, and the gates of the first transistor Q1 and the second transistor Q2 are both connected to a first gate signal EM1. The channel region of the driving transistor QT is located in the second-type active layer 20. In the first direction Y, the orthographic projections of the channel region of the first transistor Q1 and the channel region of the second transistor Q2 in the same pixel circuit PX on the substrate 11 are located on different sides of the orthographic projection of the channel region of the driving transistor QT on the substrate 11, which is beneficial for optimizing the pixel circuit layout.

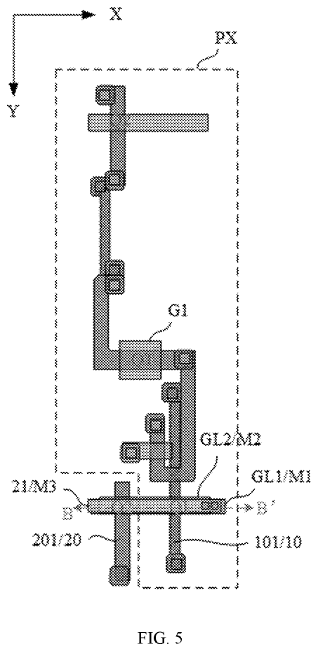

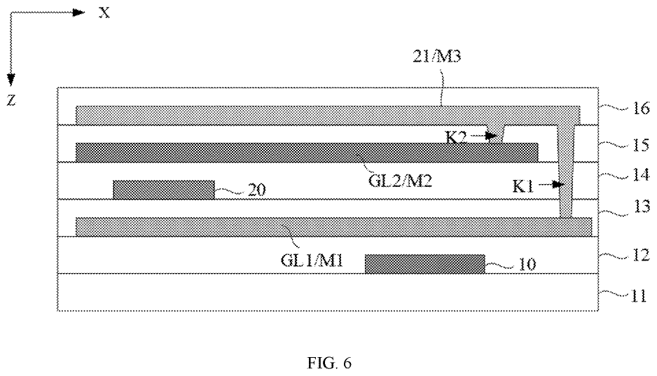

FIG. 5 is a schematic plan view of another display panel provided by an embodiment of the present disclosure, and FIG. 6 is a schematic cross-sectional view of another display panel provided by an embodiment of the present disclosure, and the structure shown in FIG. 6 is, in one embodiment, a cross-sectional structure obtained along the cutting line BB′ of the display panel shown in FIG. 5. Referring to FIGS. 5 and 6, based on the above embodiments, in one embodiment, the display panel further includes a first auxiliary signal line 21, and the first auxiliary signal line 21 is disposed in a different layer from the first gate signal line GL1 and the second gate signal line GL2. The first gate signal line GL1 is connected to the second gate signal line GL2 through the first auxiliary signal line 21 to achieve transmission of the same gate signal by the first gate signal line GL1 and the second gate signal line GL2.

In one embodiment, the display panel further includes a third conductive layer M3, the third conductive layer M3 is located on a side of the second conductive layer M2 away from the substrate 11, and the first auxiliary signal line 21 is located in the third conductive layer M3. The first gate signal line GL1 is connected to the first auxiliary signal line 21 through a first-type via K1, and the second gate signal line GL 2 is connected to the first auxiliary signal line 21 through a second-type via K2.

In this embodiment, the orthographic projection of the first gate signal line GL1 on the substrate 11, the orthographic projection of the second gate signal line GL2 on the substrate 11, and the orthographic projection of the first auxiliary signal line 21 on the substrate 11 at least partially overlap, which is beneficial for saving pixel circuit space and can simultaneously drive different types of the first transistor Q1 and the second transistor Q2.

Furthermore, since the first gate signal line GL1 and the second gate signal line GL 2 are connected via the first auxiliary signal line 21, and the first gate signal line GL 1, the second gate signal line GL 2, and the first auxiliary signal line 21 are located in different conductive layers, it is equivalent to a parallel connection of the three, which is beneficial for reducing the impedance of the gate signal lines, thereby reducing the signal delay of the gate signal lines and improving display quality.

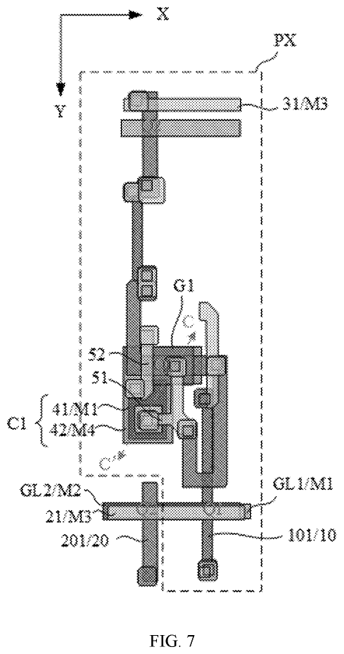

FIG. 7 is a schematic plan structural view of another display panel provided by an embodiment of the present disclosure. Referring to FIG. 7, based on the above embodiments, in one embodiment, the display panel further includes a first initialization signal line 31. The first initialization signal line 31 is located in the third conductive layer M3. The first initialization signal line 31 is connected to the first electrode of the second transistor Q2 via a second type via hole K2, and the second electrode of the second transistor Q2 is connected to the first electrode layer of the light-emitting element (not shown in the figure).

In the same pixel circuit PX, the orthographic projection of the first gate G1 of the driving transistor QT on the substrate 11 is located between the orthographic projection of the first initialization signal line 31 on the substrate 11 and the orthographic projection of the first gate signal line GL1 on the substrate 11. The orthographic projection of the first initialization signal line 31 of the current row pixel circuit PX on the substrate 11 is located on a side of the orthographic projection of the first gate signal line GL1 of the previous row pixel circuit PX on the substrate 11 that is away from the orthographic projection of the first gate G1 of the driving transistor QT of the current row pixel circuit PX on the substrate 11.

In one embodiment, the display panel further includes a fourth conductive layer M4, the fourth conductive layer M4 is located between the first conductive layer M1 and the second type active layer 20, the pixel circuit PX further includes a first capacitor C1, the first capacitor C1 includes a first plate 41 and a second plate 42 arranged in a stacked manner, the first plate 41 is located in the first conductive layer M1, the second plate 42 is located in the fourth conductive layer M4, the first gate G1 of the driving transistor QT is connected to the first plate 41 via a first connection line 51, and the second plate 42 is connected to the first electrode layer of the light-emitting element via a second connection line 52.

In this embodiment, the first gate G1 of the driving transistor QT is located in the second conductive layer M2, i.e., the first gate G1 is the top gate of the driving transistor QT, and serves as the control electrode of the driving transistor QT to be connected to the first plate 41 of the first capacitor C1.

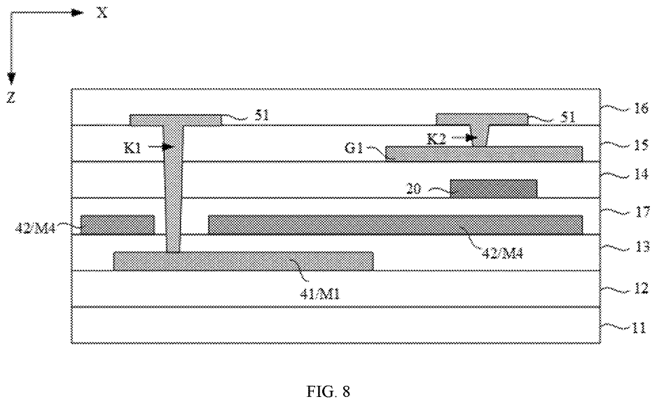

In one embodiment, FIG. 8 is a schematic cross-sectional structural view of another display panel provided by an embodiment of the present disclosure, in one embodiment a cross-sectional structure obtained along the cutting line CC′ of the display panel shown in FIG. 7.

Referring to FIG. 7 and FIG. 8, the overlapping region of the first plate 41 and the second plate 42 is the effective region of the first capacitor C1. The second plate 42 is located on a side of the first plate 41 away from the substrate 11, and an opening is provided on the second plate 42 and the first connection line 51 can be connected to the first plate 41 below the second plate 42. The first gate G1 of the driving transistor QT is connected to one end of the first connection line 51 via a second type via hole K2. The first plate 41 is connected to the other end of the first connection line 51 via a first type via hole K1. The second plate 42 is connected to one end of the second connection line 52 via a first type via hole K1. The other end of the second connection line 52 is connected to the first electrode layer of the light-emitting element (e.g., the anode layer of the light-emitting diode D1).

In one embodiment, since the second plate 42 is located below the second type active layer 20, and the orthographic projection of the second plate 42 on the substrate 11 overlaps with the orthographic projection of the channel region of the driving transistor QT on the substrate 11, the second plate 42 can be reused as the second gate of the driving transistor QT, forming the bottom gate of the driving transistor QT. Here, the second plate 42 is connected to the first electrode layer of the light-emitting element, therefore, when the light-emitting element emits light, the bottom gate of the driving transistor QT is short-circuited with the first electrode layer of the light-emitting element, maintaining the bottom gate of the driving transistor QT at a forward voltage, which is beneficial for improving the stability of the threshold voltage of the driving transistor QT, thereby improving the uniformity of the driving current and enhancing the display effect.

Continuing to refer to FIG. 7 and FIG. 8, in one embodiment, the orthographic projection of the second plate 42 on the substrate 11 at least partially covers the orthographic projection of the first gate G1 of the driving transistor QT on the substrate 11. Since the first gate G1 of the driving transistor QT is the control electrode, covering the orthographic projection of the first gate G1 on the substrate 11 with the orthographic projection of the second plate 42 on the substrate 11 can form a wraparound electric field control over the channel region of the driving transistor QT, which is beneficial for maintaining the stability of the threshold voltage of the driving transistor QT.

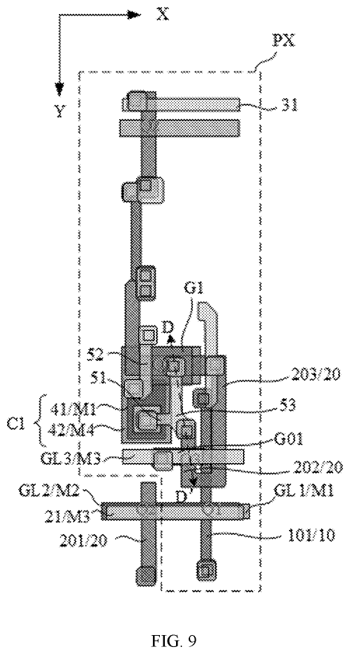

FIG. 9 is a schematic plan structural view of another display panel provided by an embodiment of the present disclosure. Referring to FIG. 4 and FIG. 9, the second type active layer 20 further includes a third active region 202, the third active region 202 extends along the first direction Y, and the third active region 202 is in the same layer as the second active region 201 and is not connected. The pixel circuit further includes a third transistor Q3. The channel region of the third transistor Q3 is located in the third active region 202, the gate G01 of the third transistor Q3 is located in the second conductive layer M2, the first electrode of the third transistor Q3 is connected to the first electrode of the driving transistor QT, and the second electrode of the third transistor Q3 is connected to the first gate G1 of the driving transistor QT via a third connection line 53. The third transistor Q3 is a compensation transistor, used for compensating the threshold voltage of the driving transistor QT, and the third transistor Q3 is connected between the first electrode of the driving transistor QT and the first gate G1.

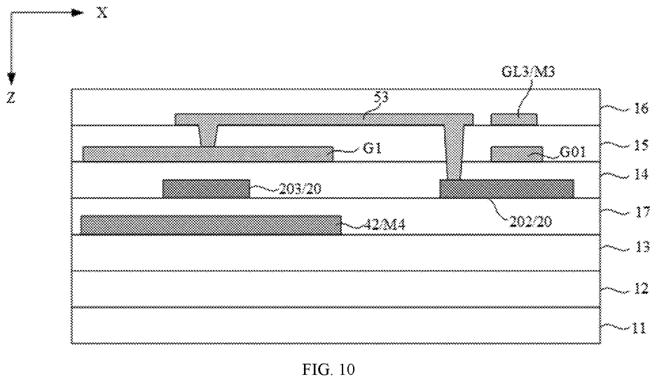

In one embodiment, FIG. 10 is a schematic cross-sectional structural diagram of another display panel provided by an embodiment of the present disclosure, in one embodiment a cross-sectional structure obtained along section line DD′ of the display panel shown in FIG. 9. Referring to FIG. 9 and FIG. 10, the channel region of the third transistor Q3 is located at an overlapping position of the orthographic projection of the gate electrode G01 of the third transistor Q3 on the third active region 202. The second electrode of the third transistor Q3 is connected to one end of the third connection line 53 via a second-type via hole K2, and the first gate electrode G1 of the driving transistor QT is connected to the other end of the third connection line 53 via the second-type via hole K2.

In one embodiment, the third connection line 53 and the first connection line 51 are of an integral structure, which facilitates simplifying the circuit layout, thereby saving pixel circuit space.

Continuing to refer to FIG. 9 and FIG. 10, the display panel further includes a third gate signal line GL3, which is connected to the gate electrode G01 of the third transistor Q3 via a second-type via hole K2, for transmitting a second gate signal EMB to the gate electrode G01 of the third transistor Q3. The orthographic projection of the third gate signal line GL3 on the substrate 11 at least partially overlaps with the orthographic projection of the gate electrode G01 of the third transistor Q3 on the substrate 11, which facilitates saving pixel circuit space. In one embodiment, in a same row of pixel circuits PX extending along the second direction X, the orthographic projection of the third gate signal line GL3 on the substrate 11 is located between the orthographic projection of the first gate signal line GL1 on the substrate 11 and the orthographic projection of the first gate electrode G1 of the driving transistor QT on the substrate 11, which facilitates the layout of the third connection line 53.

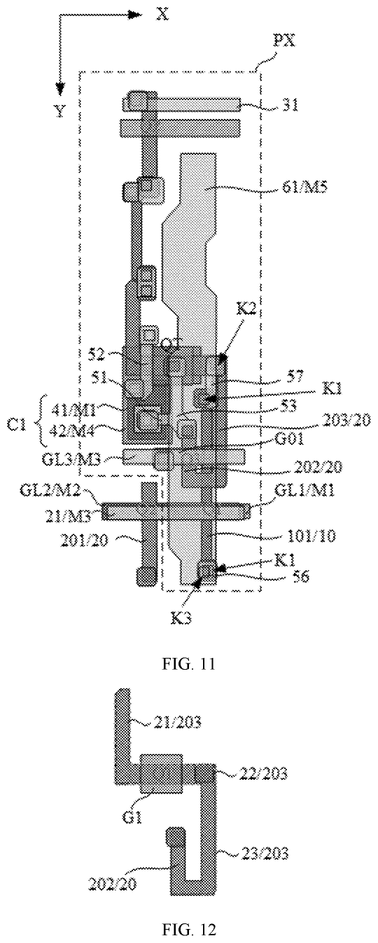

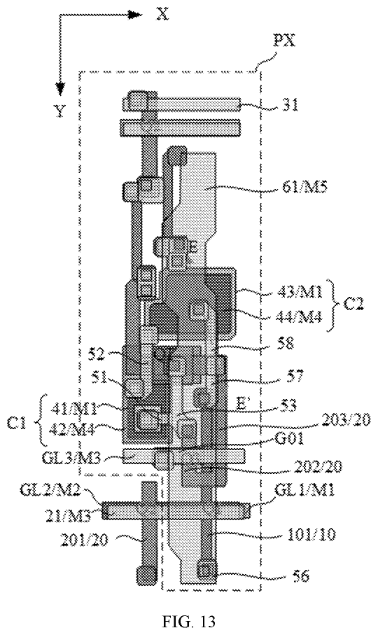

FIG. 11 is a schematic planar structural diagram of another display panel provided by an embodiment of the present disclosure, and FIG. 12 is a schematic structural diagram of a fourth active region provided by an embodiment of the present disclosure.

Referring to FIG. 11 and FIG. 12, the second-type active layer 20 further includes a fourth active region 203, which includes a first branch portion 21 extending along the first direction Y, a second branch portion 22 extending along the second direction X, and a third branch portion 23 extending along the first direction Y. The channel region of the driving transistor QT is located in the second branch portion 22, and the orthographic projection of the first gate electrode G1 of the driving transistor QT on the substrate 11 at least overlaps with the orthographic projection of the second branch portion 22 on the substrate 11. Here, the material of the second-type active layer 20 includes a metal oxide, which facilitates reducing the leakage current of the pixel circuit.

In one embodiment, the first electrode of the third transistor Q3 is connected to the first electrode of the driving transistor QT via the third branch portion 23. Here, the third active region 202 and the fourth active region 203 are connected as an integral structure, which facilitates shortening the connection distance between the third transistor Q3 and the driving transistor QT.

Continuing to refer to FIG. 11, the display panel further includes a power line 61 and a fifth conductive layer M5, the fifth conductive layer M5 is located on a side of the third conductive layer M3 away from the substrate 11. The power line 61 is located in the fifth conductive layer M5, the first electrode of the first transistor Q1 is connected to the power line 61 via a sixth connection line 56, and the second electrode of the first transistor Q1 is connected to the first electrode of the driving transistor QT via a seventh connection line 57.

In one embodiment, the first electrode of the first transistor Q1 is connected to one end of the sixth connection line 56 via a first-type via hole K1, and the power line 61 is connected to the other end of the sixth connection line 56 via a third-type via hole K3. The second electrode of the first transistor Q1 is connected to one end of the seventh connection line 57 via a first-type via hole K1, and the first electrode of the driving transistor QT is connected to the other end of the seventh connection line 57 via a second-type via hole K2.

In one embodiment, the orthographic projection of the third gate signal line GL3 on the substrate 11 overlaps with the orthographic projection of the first active region 101 on the substrate 11. That is, in the first direction Y, the first active region 101 needs to cross over the third gate signal line GL3 to avoid mutual interference between the seventh connection line 57 extending along the first direction Y and the third gate signal line GL 3 extending along the second direction X. Here, both the seventh connection line 57 and the third gate signal line GL3 are located in the third conductive layer M3.

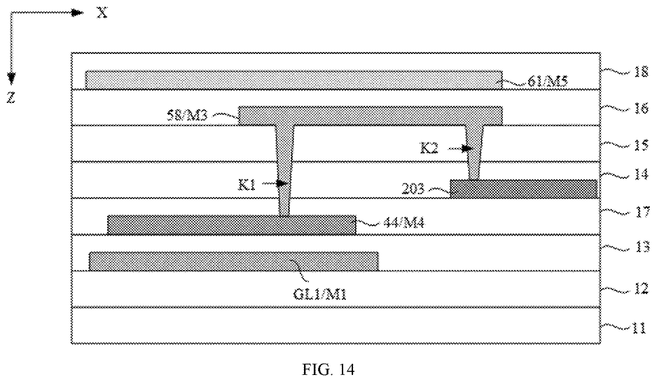

FIG. 13 is a schematic planar structural diagram of another display panel provided by an embodiment of the present disclosure, and FIG. 14 is a schematic cross-sectional structural diagram of another display panel provided by an embodiment of the present disclosure, in one embodiment a cross-sectional structure obtained along section line EE′ of the display panel shown in FIG. 13.

Referring to FIG. 4, FIG. 13, and FIG. 14, based on the above embodiments, in one embodiment, the pixel circuit PX further includes a second capacitor C2, which is a coupling capacitor for coupling a voltage related to the data voltage Vdata to the first gate electrode G1 of the driving transistor QT. The second capacitor C2 includes a third electrode plate 43 and a fourth electrode plate 44 arranged in a stacked manner. The third electrode plate 43 is located in the first conductive layer M1. The fourth electrode plate 44 is located in the fourth conductive layer M4, and the fourth electrode plate 44 is connected to the first electrode of the driving transistor QT via an eighth connection line 58. Here, the eighth connection line 58 is located in the third conductive layer M3 and is of an integral structure with the seventh connection line 57, which facilitates reducing the number of independent connection lines and optimizing the pixel circuit layout. Here, the fourth electrode plate 44 is connected to one end of the eighth connection line 58 via a first-type via hole K1, and the first electrode of the driving transistor QT is connected to the other end of the eighth connection line 58 via a second-type via hole K2. The overlapping area between the third electrode plate 43 and the fourth electrode plate 44 is the effective area of the second capacitor C2.

In this embodiment, the orthographic projection of the third electrode plate 43 on the substrate 11 covers the orthographic projection of the fourth electrode plate 44 on the substrate 11, which can make the electric field distribution more uniform, facilitating reducing the fringe electric field effect, thereby improving signal stability.

In one embodiment, in the first direction Y, the orthographic projection of the third electrode plate 43 on the substrate 11 is located on a side of the orthographic projection of the first gate electrode G1 of the driving transistor QT on the substrate 11 away from the orthographic projection of the third gate signal line GL3 on the substrate 11. That is, along the plane of the first direction Y, the first gate electrode G1 of the driving transistor QT is located between the second capacitor C2 and the third gate signal line GL3, which facilitates optimizing the pixel circuit layout.

Continuing to refer to FIG. 4, in one embodiment, the pixel circuit further includes a fourth transistor Q4 and a fifth transistor Q5, both of which are connected to the second capacitor C2, and the fourth transistor Q4 is used to transmit the data voltage Vdata on the data line, and the fifth transistor Q5 is used to transmit the second initialization voltage VRE2 on the second initialization signal line.

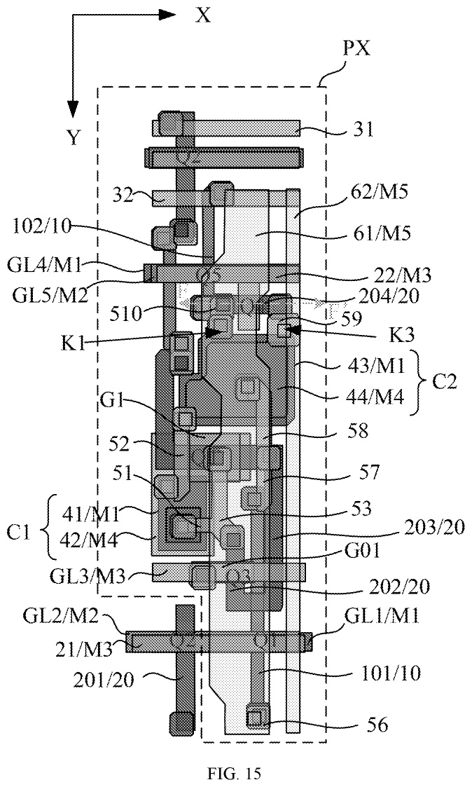

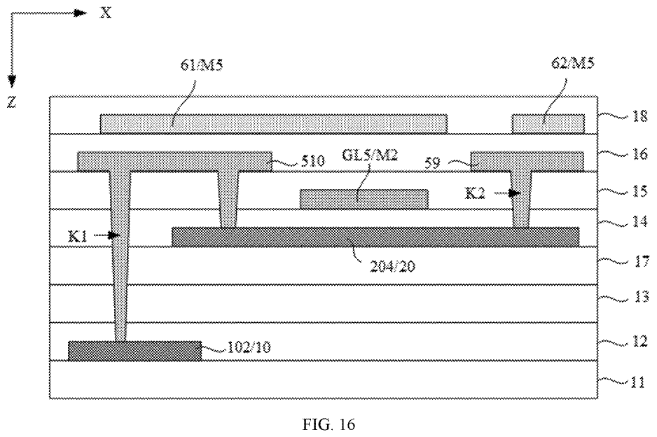

FIG. 15 is a schematic plan view of another display panel provided by an embodiment of the present disclosure, and FIG. 16 is a schematic cross-sectional view of another display panel provided by an embodiment of the present disclosure, in one embodiment a cross-sectional structure obtained along the cutting line FF′ of the display panel shown in FIG. 15.

Referring to FIGS. 15 and 16, based on the above embodiments, in one embodiment, the first type active layer 10 further includes a fifth active region 102, the second type active layer 20 further includes a sixth active region 204, the channel region of the fourth transistor Q4 is located in the sixth active region 204, and the channel region of the fifth transistor Q5 is located in the fifth active region 102. The display panel further includes a data line 62, a second initialization signal line 32, and a fifth conductive layer M5. The fifth conductive layer M5 is located on a side of the third conductive layer M3 away from the substrate 11, the data line 61 is located on the fifth conductive layer M5. The second initialization signal line 32 is located on the third conductive layer M3, a first electrode of the fourth transistor Q4 is connected to the data line 62 via a ninth connection line 59, a second electrode of the fourth transistor Q4 is connected to the third electrode plate 43 via a tenth connection line 510. A first electrode of the fifth transistor Q5 is connected to the second initialization signal line 32, and a second electrode of the fifth transistor Q5 is connected to the tenth connection line 510. Here, the first electrode of the fourth transistor Q4 is connected to one end of the ninth connection line 59 via a second type via K2, the data line 62 is connected to the other end of the ninth connection line 59 via a third type via K3, the second electrode of the fourth transistor Q4 is connected to one end of the tenth connection line 510 via a second type via K2, and the third electrode plate 43 is connected to the other end of the tenth connection line 510 via a first type via K1. The first electrode of the fifth transistor Q5 is connected to the second initialization signal line 32 via a first type via K1, and the second electrode of the fifth transistor Q5 is connected to the tenth connection line 510 via a first type via K1.

In one embodiment, the display panel includes a fourth gate signal line GL4 and a fifth gate signal line GL5, the channel region of the fourth transistor Q4 is located at a position overlapping the orthographic projection of the fifth gate signal line GL5 on the sixth active region 204. The channel region of the fifth transistor Q5 is located at a position overlapping the orthographic projection of the fourth gate signal line GL4 on the fifth active region 102. Here, the fifth gate signal line GL5 serves as the gate of the fourth transistor Q4, the fourth gate signal line GL4 serves as the gate of the fifth transistor Q5, and the fourth gate signal line GL4 and the fifth gate signal line GL5 transmit the same gate signal, for example, both transmit the third gate signal EM2.

In one embodiment, the fifth active region 102 extends along a first direction Y, the sixth active region 204 extends along a second direction X, and the fifth active region 102 and the sixth active region 204 do not intersect. The fifth gate signal line GL5 includes a main body portion and a branch portion. The fourth gate signal line GL4 and the main body portion of the fifth gate signal line GL5 both extend along the second direction X. The branch portion of the fifth gate signal line GL5 extends along the first direction Y, and the channel region of the fourth transistor Q4 is located at a position where the branch portion of the fifth gate signal line GL5 overlaps the sixth active layer 204, and the first direction Y intersects the second direction X.

In this embodiment, the orthographic projection of the fourth gate signal line GL4 on the substrate 11 is located on a side of the orthographic projection of the third electrode plate 43 on the substrate 11 away from the orthographic projection of the first gate G1 of the driving transistor QT on the substrate 11. The orthographic projection of the third gate signal line GL3 on the substrate 11 and the orthographic projection of the fourth gate signal line GL4 on the substrate 11 are respectively located on different sides of the orthographic projection of the first gate G1 of the driving transistor QT on the substrate 11. Since the fourth gate signal line GL4 and the fifth gate signal line GL5 transmit the same signal, the orthographic projection of the fourth gate signal line GL4 on the substrate 11 can be set to at least partially overlap the orthographic projection of the fifth gate signal line GL5 on the substrate 11 to save pixel circuit space. For example, the orthographic projection of the main body portion of the fifth gate signal line GL5 on the substrate 11 overlaps the orthographic projection of the fourth gate signal line GL4 on the substrate 11.

Continuing to refer to FIG. 15, in one embodiment, the display panel further includes a second auxiliary signal line 22, the second auxiliary signal line 22 is disposed on a different layer from the fourth gate signal line GL4 and the fifth gate signal line GL5, and the fourth gate signal line GL4 is connected to the fifth gate signal line GL5 via the second auxiliary signal line 22. Through this arrangement, the resistance of the gate signal line can be reduced, and signal delay can be decreased. At the same time, it can serve as the gate of both a P-type transistor and an N-type transistor, which is beneficial for saving pixel circuit space.

The fourth gate signal line GL4 is located on the first conductive layer M1, the fifth gate signal line GL5 is located on the second conductive layer M2, the second auxiliary signal line 22 is located on the third conductive layer M3, the fourth gate signal line GL 4 is connected to the second auxiliary signal line 22 via a first type via K1, and the fifth gate signal line GL 5 is connected to the second auxiliary signal line 22 via a second type via K2. Here, the specific connection structure of the fourth gate signal line GL 4, the fifth gate signal line GL 5, and the second auxiliary signal line 22 can refer to the connection relationship of the first gate signal line GL1, the second gate signal line GL 2, and the first auxiliary signal line 21, which will not be repeated here.

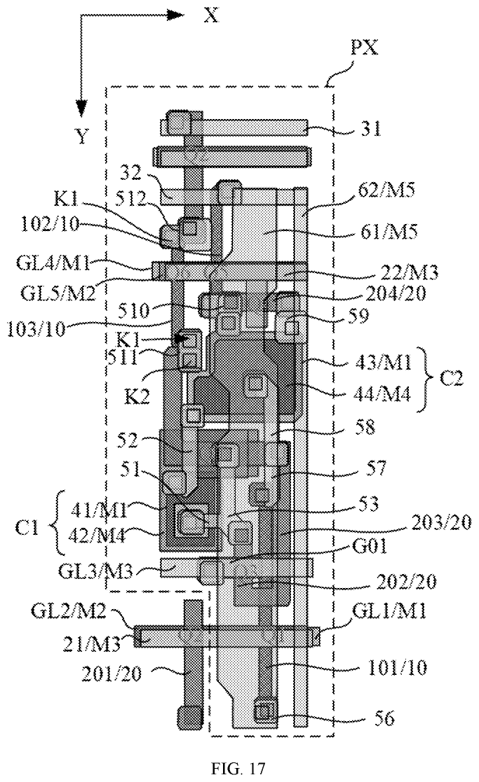

FIG. 17 is a schematic plan view of another display panel provided by an embodiment of the present disclosure. Referring to FIGS. 4 and 17, based on the above embodiments, in one embodiment, the pixel circuit PX further includes a sixth transistor Q6, the sixth transistor Q6 is connected between the second electrode of the driving transistor QT and the first electrode of the light-emitting diode D1.

In one embodiment, the first type active layer 10 further includes a seventh active region 103, the seventh active region 103 extends along the first direction Y, the seventh active region 103 is in the same layer as the fifth active region 102 and is not connected thereto. A channel region of the sixth transistor Q6 is located in the seventh active region 103, in one embodiment at an overlapping position of an orthographic projection of the fourth gate signal line GL4 on the seventh active region 103. A first electrode of the sixth transistor Q6 is connected to a second electrode of the driving transistor QT via an eleventh connection line 511, and a second electrode of the sixth transistor Q6 is connected to a first electrode layer of the light-emitting element (i.e., a first electrode of the light-emitting diode D1) via a twelfth connection line 512. In one embodiment, the first electrode of the sixth transistor Q6 is connected to one end of the eleventh connection line 511 via a first type via K1, the second electrode of the driving transistor QT is connected to the other end of the eleventh connection line 511 via a second type via K2, and the second electrode of the sixth transistor Q6 is connected to the twelfth connection line 512 via a first type via K1.

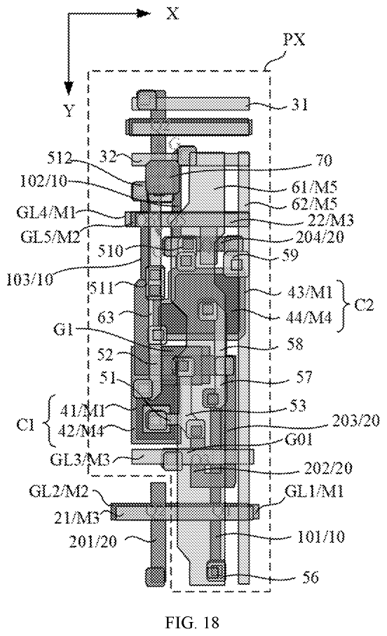

FIG. 18 is a schematic plan view of another display panel provided by an embodiment of the present disclosure. Referring to FIG. 18, based on the above embodiments, in one embodiment, the display panel further includes a first electrode line 63 and a first electrode layer 70, a power line 61, a data line 62, and the first electrode line 63 all extend along the first direction Y, the power line 61, the data line 62, and the first electrode line 63 are located in a fifth conductive layer M5, and the first electrode layer 70 is located on a side of the fifth conductive layer M5 away from a substrate 11.

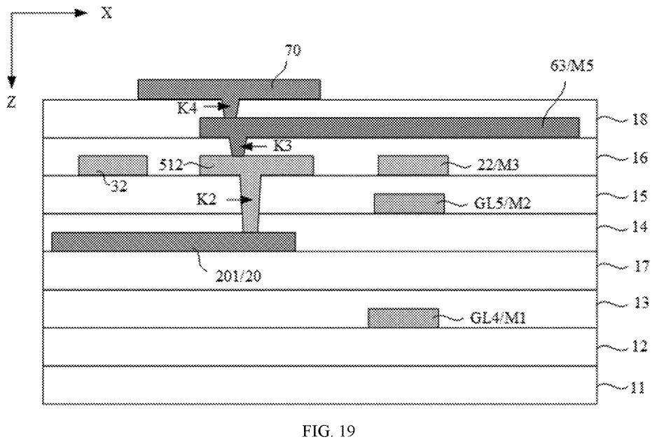

FIG. 19 is a schematic cross-sectional view of another display panel provided by an embodiment of the present disclosure, in one embodiment a cross-sectional view of the display panel shown in FIG. 18 taken along a cutting line GG′. Referring to FIG. 18 and FIG. 19, the first electrode layer 70 is connected to the first electrode line 63 via a fourth type via K4, the first electrode line 63 is then connected to the twelfth connection line 512 via a third type via K3, and the twelfth connection line 512 is connected to a second active region 201 via a second type via K2, i.e., connected to a second transistor Q2.

Continuing to refer to FIG. 18, in the second direction X, an orthographic projection of the data line 62 on the substrate 11 is located on a side of an orthographic projection of the power line 61 on the substrate 11 away from an orthographic projection of a first gate G1 of the driving transistor QT on the substrate 11. The orthographic projection of the data line 62 on the substrate 11 is located on a side of the orthographic projection of the power line 61 on the substrate 11 away from an orthographic projection of the first electrode line 63 on the substrate 11. That is, in the same pixel circuit PX, the first electrode line 63, the power line 31, and the data line 62 are sequentially arranged along the second direction X, and the data line 62 is away from the first gate G1 of the driving transistor QT and the first capacitor C1, and the power line 61 can shield signals between the data line 62 and the first gate G1 of the driving transistor QT, preventing signal crosstalk, which is beneficial for reducing the degree of signal crosstalk in the first direction Y, thereby improving the display effect.

In one embodiment, a line width of the power line 61 is greater than line widths of the data line 62 and the first electrode line 63, and an orthographic projection of the power line 61 on the substrate 11 at least covers orthographic projections of channel regions of some transistors on the substrate 11. An orthographic projection of the first electrode layer 70 on the substrate 11 at least covers orthographic projections of channel regions of some transistors on the substrate 11.

In one embodiment, by having the power line 61 and the first electrode line 63 located in the fifth conductive layer M5, can cover at least most of the channel regions of the transistors to achieve a top light-shielding effect, avoiding adverse effects of external light on the transistors, which is beneficial for enhancing the stability of the panel, thereby improving the display effect.

In one embodiment, referring to the cross-sectional structures in the above embodiments, the display panel further includes a first insulating layer 12, a second insulating layer 13, a third insulating layer 17, a fourth insulating layer 14, a fifth insulating layer 15, a sixth insulating layer 16, and a seventh insulating layer 18. The first insulating layer 12 is located between the first type active layer 10 and the first conductive layer M1, the second insulating layer 13 is located between the first conductive layer M1 and the fourth conductive layer M4. The third insulating layer 17 is located between the fourth conductive layer M4 and the second type active layer 20, the fourth insulating layer 14 is located between the second type active layer 20 and the second conductive layer M2, the fifth insulating layer 15 is located between the second conductive layer M2 and the third conductive layer M3, the sixth insulating layer 16 is located between the third conductive layer M3 and the fifth conductive layer M5, and the seventh insulating layer 18 is located between the fifth conductive layer M5 and the first electrode layer 70.

The display panel includes a first type via K1, a second type via K2, a third type via K3, and a fourth type via K4. In one embodiment, the first type via K1 penetrates the fifth insulating layer 15, the fourth insulating layer 14, and the third insulating layer 17 (i.e., from the third conductive layer M3 to the fourth conductive layer M4), or the first type via K1 penetrates the fifth insulating layer 15, the fourth insulating layer 14, the third insulating layer 17, and the second insulating layer 13 (i.e., from the third conductive layer M3 to the first conductive layer M1), or the first type via K1 penetrates the fifth insulating layer 15, the fourth insulating layer 14, the third insulating layer 17, the second insulating layer 13, and the first insulating layer 12 (i.e., from the third conductive layer M3 to the first type active layer 10). The second type via K2 penetrates the fifth insulating layer 15 (i.e., from the third conductive layer M3 to the second conductive layer M2), or the second type via K2 penetrates the fifth insulating layer 15 and the fourth insulating layer 14 (i.e., from the third conductive layer M3 to the second type active layer 20). The third type via K3 penetrates the sixth insulating layer 16 (i.e., from the fifth conductive layer M5 to the third conductive layer M3), and the fourth type via K4 penetrates the seventh insulating layer 18 (i.e., from the first electrode layer 70 to the fifth conductive layer M5).

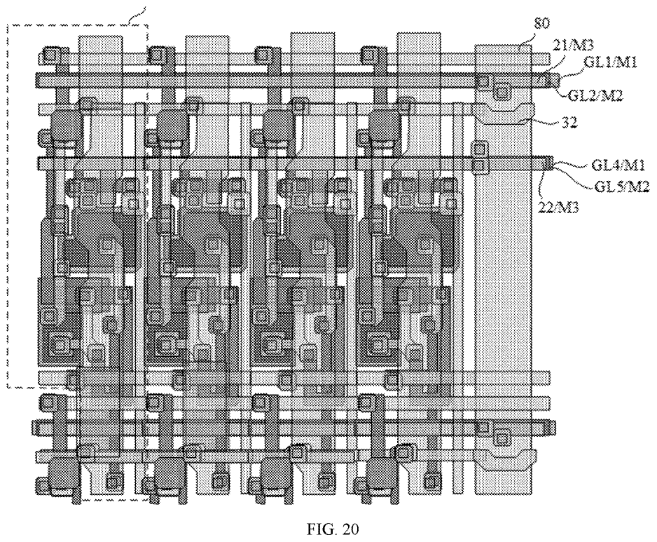

FIG. 20 is a schematic plan view of another display panel according to an embodiment of the present disclosure. Referring to FIG. 20, based on the above embodiments, in one embodiment, the display panel further includes a spare signal line 80, the spare signal line 80 is located in a fifth conductive layer M5, the spare signal line 80 extends along a first direction Y, and along a second direction X, adjacent spare signal lines 80 are spaced apart by M pixel circuits PX.

Orthographic projections of connection holes between the first gate signal line GL 1, the second gate signal line GL 2, and the first auxiliary signal line 21 on the substrate 11 at least partially overlap with an orthographic projection of the spare signal line 80 on the substrate 11. Correspondingly, orthographic projections of connection holes between the fourth gate signal line GL4, the fifth gate signal line GL5, and the second auxiliary signal line 22 on the substrate 11 at least partially overlap with the orthographic projection of the spare signal line 80 on the substrate 11. The purpose of this arrangement is that, since there is no pixel circuit PX below the spare signal line 80, disposing the connection holes in the region where the spare signal line 80 is located can reduce the number of via holes in the pixel circuit PX, which is beneficial for reducing parasitic parameters of the circuit and improving signal integrity.

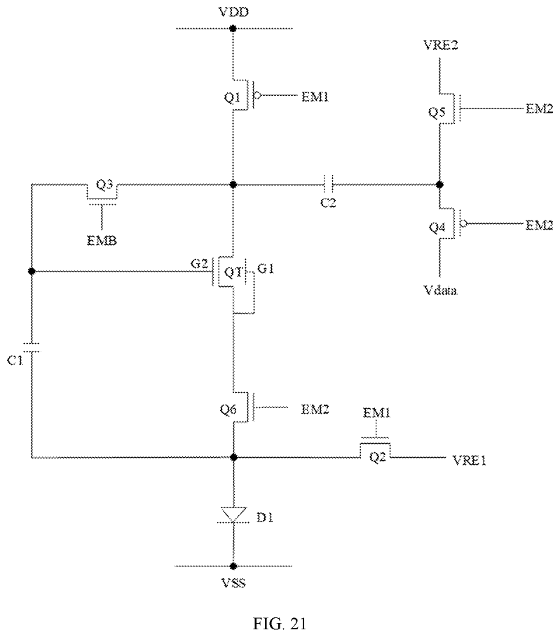

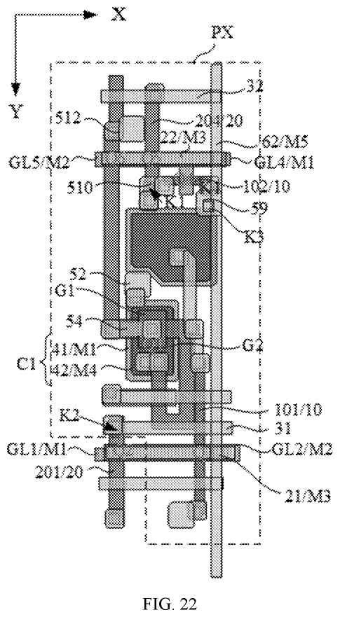

In one embodiment, M is an integer greater than or equal to 2 and less than or equal to 12. FIG. 21 is a schematic structural diagram of another pixel circuit according to an embodiment of the present disclosure, and FIG. 22 is a schematic plan view of another display panel according to an embodiment of the present application.

Referring to FIG. 21 and FIG. 22, the difference from the structure shown in FIG. 15 is that, in this embodiment, the fourth transistor Q4 is a P-type transistor, and the fifth transistor Q5 and the sixth transistor Q6 are N-type transistors. In one embodiment, the first type active layer 10 further includes a fifth active region 102, the second type active layer 20 further includes a sixth active region 204, a channel region of the fourth transistor Q4 is located in the fifth active region 102, and a channel region of the fifth transistor Q5 is located in the sixth active region 204. In one embodiment, a first electrode of the fourth transistor Q4 is connected to one end of a ninth connection line 59 via a first type via hole K1, a data line 62 is connected to the other end of the ninth connection line 59 via a third type via hole K3, a second electrode of the fourth transistor Q4 is connected to one end of a tenth connection line 510 via the first type via hole K1, and a third electrode plate 43 is connected to the other end of the tenth connection line 510 via the first type via hole K1. A first electrode of the fifth transistor Q5 is connected to a second initialization signal line 32 via a second type via hole K2, and a second electrode of the fifth transistor Q5 is connected to the tenth connection line 510 via the second type via hole K2.

In this embodiment, the channel region of the fourth transistor Q4 is located at a position where the fourth gate signal line GL4 orthographically projects onto the fifth active region 102, and the channel region of the fifth transistor Q5 is located at a position where the fifth gate signal line GL5 orthographically projects onto the sixth active region 204. Here, the fifth gate signal line GL5 serves as a gate of the fifth transistor Q5, the fourth gate signal line GL4 serves as a gate of the fourth transistor Q4, and the fourth gate signal line GL4 and the fifth gate signal line GL5 transmit the same gate signal.

In one embodiment, the sixth active region 204 extends along the first direction Y, the fifth active region 102 extends along the second direction X, and the fifth active region 102 and the sixth active region 204 do not intersect. The fourth gate signal line GL4 includes a main body portion and a branch portion, the fifth gate signal line GL5 and the main body portion of the fourth gate signal line GL4 both extend along the second direction X, the branch portion of the fourth gate signal line GL4 extends along the first direction Y, and the channel region of the fourth transistor Q4 is located at a position where the branch portion of the fourth gate signal line GL4 overlaps the fifth active region 102.

In this embodiment, an orthographic projection of the fourth gate signal line GL4 on the substrate 11 is located on a side of an orthographic projection of the third electrode plate 43 on the substrate 11 away from an orthographic projection of the first gate G1 of the driving transistor QT on the substrate 11. An orthographic projection of the third gate signal line GL3 on the substrate 11 and the orthographic projection of the fourth gate signal line GL4 on the substrate 11 are located on different sides of the orthographic projection of the first gate G1 of the driving transistor QT on the substrate 11. Similar to the structure shown in FIG. 15, the orthographic projection of the fourth gate signal line GL4 on the substrate 11 at least partially overlaps with the orthographic projection of the fifth gate signal line GL5 on the substrate 11, for example, the orthographic projection of the main body portion of the fourth gate signal line GL4 on the substrate 11 overlaps with the orthographic projection of the fifth gate signal line GL5 on the substrate 11, to save pixel circuit space.

In one embodiment, a channel region of the sixth transistor Q6 is located in a fourth active region 203, a first electrode of the sixth transistor Q6 is connected to a second electrode of the driving transistor QT via the fourth active region 203, and a second electrode of the sixth transistor Q6 is connected to a first electrode layer of a light-emitting element via a twelfth connection line 512.

In one embodiment, the channel region of the sixth transistor Q6 is located at an overlapping position of an orthographic projection of a fifth gate signal line GLM on the fourth active region 203. The second electrode of the sixth transistor Q6 is connected to one end of the twelfth connection line 512 via a second type via hole K2, and the first electrode layer of the light-emitting element is connected to the other end of the twelfth connection line 512.

In this embodiment, by disposing the channel region of the sixth transistor Q6 in the fourth active region 203, the fourth active region 203 can extend along the first direction Y and intersect with the fourth gate signal line GL4, and the sixth transistor Q6 and the driving transistor QT do not need to be bridged through the third conductive layer M3, and can be directly connected through the second type active layer 20, which is beneficial for optimizing the pixel circuit layout.

In one embodiment, in this embodiment, a second gate G2 of the driving transistor QT is a control electrode, i.e., a bottom gate is the control electrode, the second gate G2 of the driving transistor QT is connected to a second electrode plate 42 (the second electrode plate 42 can be reused as the second gate G2 of the driving transistor QT), and a first gate G1 of the driving transistor QT is connected to the second electrode of the driving transistor QT via a fourth connection line 54. In one embodiment, the second electrode of the driving transistor QT can be a source electrode.

Among them, the first gate G1 of the driving transistor QT is connected to one end of the fourth connection line 54 via a second-type via hole K2, and the second electrode of the driving transistor QT is connected to the other end of the fourth connection line 54 via a second-type via hole K2. The first electrode plate 41 is connected to the first electrode layer of the light-emitting element via the second connection line 52. The orthographic projection of the first electrode plate 41 on the substrate 11 at least partially overlaps with the orthographic projection of the second gate G2 of the driving transistor QT on the substrate 11, and the orthographic projection of the second gate G2 of the driving transistor QT on the substrate 11 at least partially overlaps with the orthographic projection of the first gate G1 of the driving transistor QT on the substrate 11, and the channel region of the driving transistor QT can be shielded from light by the first electrode plate 41.

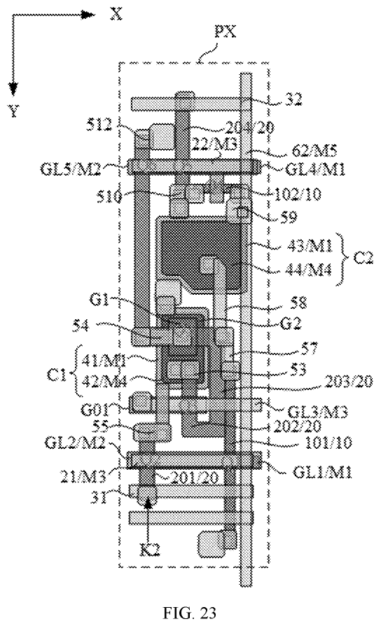

In this embodiment, the parts identical to the structure shown in FIG. 15 are not described again, and reference can be made to the description of FIG. 15 for details, which have the same beneficial effects. FIG. 23 is a schematic plan view of another display panel provided by an embodiment of the present application. Referring to FIG. 23, in a direction perpendicular to the substrate 11, the overlapping positions of the same gate signal line with the first active region 101 and the second active region 201 form the gate of the first transistor Q1 and the gate of the second transistor Q2 of the same pixel circuit PX. The first transistor Q1 is used to transmit the first power signal VDD to the driving transistor QT of the pixel circuit PX, and the second transistor Q2 is used to transmit the first initialization signal VRE1 to the light-emitting element connected to the pixel circuit PX. Among them, the first transistor Q1 and the second transistor Q2 are located in the same pixel circuit PX, the overlapping position of the first gate signal line GL1 and the first active region 101 forms the gate of the first transistor Q1 of the current row pixel circuit PX, and the overlapping position of the second gate signal line GL2 and the second active region 201 forms the gate of the second transistor Q2 of the current row pixel circuit PX. The orthographic projections of the channel region of the first transistor Q1 and the channel region of the second transistor Q2 in the same pixel circuit PX on the substrate 11 are located on the same side of the orthographic projection of the channel region of the driving transistor QT on the substrate 11.

In this embodiment, it is not necessary to use the gate signal line of the previous row to form the second transistor Q2 in the current row pixel circuit PX, which is beneficial to simplifying the design of the special-shaped display area in the arc area and reducing the design difficulty. Furthermore, to match the above design scheme, compared with the scheme in FIG. 22 where the first initialization signal line 21 is located above the first gate signal line GL1 in the first direction Y. In this embodiment, the first initialization signal line 31 needs to be moved to below the first gate signal line GL 1. That is, for the same row of pixel circuits PX extending along the second direction X, the orthographic projection of the first initialization signal line 31 on the substrate 11 is located on the side of the orthographic projection of the first gate signal line GL1 on the substrate 11 away from the orthographic projection of the first gate G1 of the driving transistor QT on the substrate 11.

In one embodiment, the first initialization signal line 31 is connected to the first electrode of the second transistor Q2 via a second-type via hole K2, the second electrode of the second transistor Q2 is connected to one end of the fifth connection line 55 via a second-type via hole K2, and the first electrode plate 41 is connected to the other end of the fifth connection line 55 via a first-type via hole K1.

In one embodiment, the channel region of the third transistor Q3 is spaced apart from the channel region of the driving transistor QT, the first electrode of the third transistor Q3 is connected to the first electrode of the driving transistor QT, and the second electrode of the third transistor Q3 is connected to the second gate G2 of the driving transistor QT via the third connection line 53. Among them, the second electrode of the third transistor Q3 is connected to one end of the third connection line via a second-type via hole K2, and the other end of the third connection line is connected to the second gate of the driving transistor QT via a second-type via hole K2.

In this embodiment, in the same row of pixel circuits PX extending along the second direction X, the orthographic projection of the third gate signal line GL3 on the substrate 11 is located between the orthographic projection of the first gate signal line GL1 on the substrate 11 and the orthographic projection of the second gate G2 of the driving transistor QT on the substrate 11. The third gate signal line GL3 extends along the second direction X, and the orthographic projection of the third gate signal line GL3 on the substrate 11 overlaps with the orthographic projection of the first electrode plate 41 on the substrate 11, to facilitate the connection between the second transistor Q2 and the first electrode plate 41.

The embodiments of the present application, by moving the first initialization signal line 31 to below the first gate signal line GL 1, and connecting the first electrode plate 41 of the first capacitor C1 to the second transistor Q2 through the third gate signal line GL3, allows the second transistor Q2 in the same pixel circuit PX to be formed by the overlapping of the second gate signal line GL2 in the current row pixel circuit PX with the second active region 201, thereby eliminating the need to use the second gate signal line GL2 in the previous or next row pixel circuit PX, which is beneficial to simplifying the design of the special-shaped display area at the arc area and reducing the complexity of the pixel circuit.

In one embodiment, in another optional implementation provided by the embodiment of the present application, the first transistor Q1 and the second transistor Q2 can also be an initialization transistor and a data writing transistor connected to the second capacitor C2, i.e., corresponding to the fifth transistor Q5 and the fourth transistor Q4 in the above embodiments.

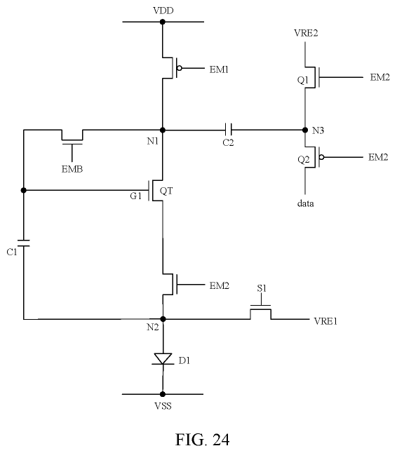

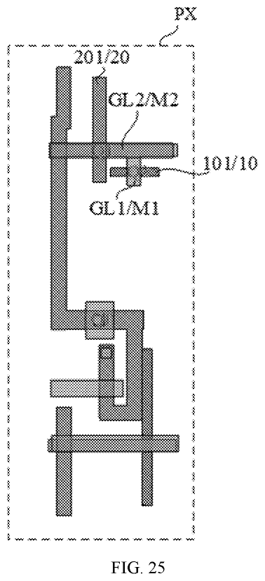

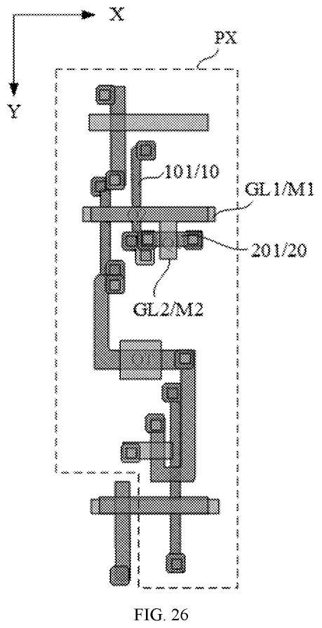

FIG. 24 is a schematic structural diagram of another pixel circuit provided by an embodiment of the present application, FIG. 25 is a schematic plan view of another display panel provided by an embodiment of the present application, and FIG. 26 is a schematic plan view of another display panel provided by an embodiment of the present application. Referring to FIG. 24, FIG. 25, FIG. 26, and the cross-sectional structural schematic diagram of the display panel, in a direction perpendicular to the substrate 11, the overlapping positions of the same gate signal line with the first active region 101 and the second active region 201 form the gate of the first transistor Q1 and the gate of the second transistor Q2 of the same pixel circuit PX. The first active region 101 extends along the second direction X, the second active region 201 extends along the first direction Y, the first transistor Q1 is used to transmit the second initialization signal VRE2 to the driving transistor QT of the current row pixel circuit PX, and the second transistor Q2 is used to transmit the data signal Vdata to the driving transistor QT of the current row pixel circuit PX (as shown in FIG. 25).

In one embodiment, the channel region of the driving transistor QT is located in the second type active layer 20, and the orthographic projections of the channel region of the first transistor Q1 and the channel region of the second transistor Q2 in the same pixel circuit PX on the substrate 11 are located on the same side of the orthographic projection of the channel region of the driving transistor QT on the substrate 11. The gate signal lines include a first gate signal line GL1 and a second gate signal line GL2, the first gate signal line GL1 is located in the first conductive layer M1, and the overlapping position of the first gate signal line GL1 and the first active region 101 forms the gate of the second transistor Q2, the second gate signal line GL2 is located in the second conductive layer M2, and the overlapping position of the second gate signal line GL2 and the second active region 201 forms the gate of the first transistor Q1. The first active region 101 extends along the first direction Y, the second active region 201 extends along the second direction X, the first transistor Q1 is used to transmit a data signal Vdata to the driving transistor QT of the pixel circuit PX in the current row, and the second transistor Q2 is used to transmit a second initialization signal VRE2 to the driving transistor QT of the pixel circuit PX in the current row (as shown in FIG. 26). In FIGS. 25 and 26, only the positions and transmitted signals of the first transistor Q1 and the second transistor Q2 are different, and the overall pixel circuit structure is the same as the embodiments. For details, reference may be made to the relevant descriptions in the above embodiments, which will not be repeated.

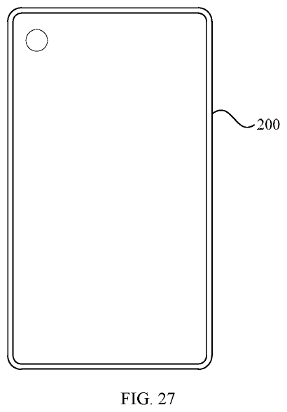

In one embodiment, an embodiment of the present application further provides a display device, which includes the display panel provided by any embodiment of the present application. Therefore, the display device also has the beneficial effects described in any of the above embodiments. FIG. 27 is a schematic structural diagram of a display device provided by an embodiment of the present application.

In this embodiment, the display device 200 can be a mobile phone, or any electronic product with a display function, including but not limited to the following categories: display panels in products such as televisions, notebook computers, desktop monitors, tablet computers, digital cameras, smart bracelets, smart glasses, vehicle displays, medical equipment, industrial control equipment, and touch interactive terminals. The embodiment of the present application does not limit this. Various forms of procedures shown above can be used, with steps reordered, added, or deleted. For example, the steps described in the present application can be executed in parallel, sequentially, or in different orders, as long as the desired results of the embodiments of the present application can be achieved, and no limitation is made herein. The above specific implementations do not constitute a limitation on the protection scope of the present application. It should be understood that various modifications, combinations, sub-combinations, and substitutions can be made according to design requirements and other factors. Any modifications, equivalent replacements, and improvements made within the spirit and principle of the present application shall be included within the protection scope of the present application.

What is claimed is

1. A display panel, comprising:
a substrate;
a first type active layer located on one side of the substrate;
a second type active layer located on a side of the first type active layer away from the substrate;
a first transistor, a channel region of the first transistor being located in the first type active layer;
a second transistor, a channel region of the second transistor being located in the second type active layer;
a first conductive layer located on a side of the first type active layer away from the substrate;
a second conductive layer located on a side of the second type active layer away from the substrate;
a gate signal line at least partially located in the first conductive layer and the second conductive layer, the gate signal line being used to transmit a same gate signal to the first transistor and the second transistor.

2. The display panel according to claim 1, wherein the first type active layer comprises a first active region, and the second type active layer comprises a second active region;
in a direction perpendicular to the substrate, an overlapping position of a same gate signal line with the first active region forms a gate of the first transistor, and an overlapping position with the second active region forms a gate of the second transistor;
the display panel comprises a plurality of rows of pixel circuits arranged in sequence, the first transistor is located in any one row of the pixel circuits, and the second transistor is located in a row of pixel circuits adjacent to the row where the first transistor is located;
the first active region and the second active region extend along a first direction, and orthographic projections of the first active region and the second active region on the substrate are arranged along a second direction;
the first transistor is used to transmit a first power signal to a driving transistor, the first transistor and the driving transistor are disposed within one pixel circuit, the second transistor is used to transmit a first initialization signal to a light-emitting element, and the second transistor is arranged in another pixel circuit;
the gate signal line comprises a first gate signal line and a second gate signal line, the first gate signal line is located in the first conductive layer, the first gate signal line comprises the gate of the first transistor, the second gate signal line is located in the second conductive layer, and the second gate signal line comprises the gate of the second transistor.

3. The display panel according to claim 1, wherein the first type active layer comprises a first active region, and the second type active layer comprises a second active region;
in a direction perpendicular to the substrate, an overlapping position of a same gate signal line with the first active region forms a gate of the first transistor, and an overlapping position with the second active region forms a gate of the second transistor, the first transistor and the second transistor being located in the same pixel circuit;
the display panel further comprises a driving transistor, the first active region extends along a second direction, the second active region extends along a first direction, the first transistor is used to transmit a second initialization signal to the driving transistor, the second transistor is used to transmit a data signal to the driving transistor;
the gate signal line comprises a first gate signal line and a second gate signal line, the first gate signal line is located in the first conductive layer, an overlapping position of the first gate signal line with the first active region forms the gate of the first transistor, the second gate signal line is located in the second conductive layer, and an overlapping position of the second gate signal line with the second active region forms the gate of the second transistor.

4. The display panel according to claim 1, wherein the first type active layer comprises a first active region, and the second type active layer comprises a second active region, the first active region extends along a first direction, the second active region extends along a second direction, the first transistor is used to transmit the data signal to the driving transistor, the second transistor is used to transmit the second initialization signal to the driving transistor, and the first transistor and the second transistor are located in the same pixel circuit;
the gate signal line comprises a first gate signal line and a second gate signal line, the first gate signal line is located in the first conductive layer, an overlapping position of the first gate signal line with the first active region forms the gate of the second transistor, the second gate signal line is located in the second conductive layer, and an overlapping position of the second gate signal line with the second active region forms the gate of the second transistor.

5. The display panel according to claim 1, wherein the first type active layer comprises a first active region, and the second type active layer comprises a second active region;
in a direction perpendicular to the substrate, a same gate signal line overlaps with the first active region to form a gate of the first transistor, and overlaps with the second active region to form a gate of the second transistor, the first transistor and the second transistor being located in a same pixel circuit;
the first active region and the second active region extend along a first direction, and orthographic projections of the first active region and the second active region on the substrate are arranged along a second direction, the first transistor is configured to transmit a first power signal to a driving transistor of the pixel circuit, the second transistor is configured to transmit a first initialization signal to a light-emitting element connected to the pixel circuit, the first transistor and the second transistor being located in a same pixel circuit;
the gate signal line comprises a first gate signal line and the second gate signal line, the first gate signal line being located in the first conductive layer, the first gate signal line comprising the gate of the first transistor, the second gate signal line being located in the second conductive layer, the second gate signal line comprising the gate of the second transistor.

6. The display panel according to claim 2, wherein the display panel further comprises a first auxiliary signal line, the first auxiliary signal line being disposed in a different layer from the first gate signal line and the second gate signal line; the first gate signal line being connected to the second gate signal line via the first auxiliary signal line, the first gate signal line is connected to the first auxiliary signal line through a first type via hole, and the second gate signal line is connected to the first auxiliary signal line through a second type via hole;
the display panel further comprises a third conductive layer, the third conductive layer being located on a side of the second conductive layer away from the substrate, the first auxiliary signal line being located in the third conductive layer;
an orthographic projection of the first gate signal line on the substrate, an orthographic projection of the second gate signal line on the substrate, and an orthographic projection of the first auxiliary signal line on the substrate at least partially overlap.

7. The display panel according to claim 2, wherein the display panel further comprises a first initialization signal line and a third conductive layer;
the third conductive layer being located on a side of the second conductive layer away from the substrate, the first initialization signal line being located in the third conductive layer, the first initialization signal line being connected to a first electrode of the second transistor through a second type via hole, a second electrode of the second transistor being connected to a first electrode layer of a light-emitting element;
in a same pixel circuit, an orthographic projection of a first gate of the driving transistor on the substrate is located between an orthographic projection of the first initialization signal line on the substrate and an orthographic projection of the first gate signal line on the substrate;
an orthographic projection of a portion of the first initialization signal line on the substrate is located on a side of the orthographic projection of the first gate signal line on the substrate away from the orthographic projection of the first gate of the driving transistor on the substrate, wherein the second transistor connected to the first initialization signal line and the driving transistor are located in a same pixel circuit, and the first gate signal line is connected to the first transistor of a pixel circuit in an adjacent row;
the first gate of the driving transistor is located in the second conductive layer.

8. The display panel according to claim 7, wherein the second type active layer further comprises a third active region, the third active region extending along the first direction, the third active region and the second active region being disposed in a same layer, and the third active region being spaced apart from the second active region;
the pixel circuit further comprises a third transistor, a channel region of the third transistor being located in the third active region, a gate of the third transistor being located in the second conductive layer, a first electrode of the third transistor being connected to the first electrode of the driving transistor, a second electrode of the third transistor being connected to the first gate of the driving transistor via a third connection line;
the display panel further comprises a third gate signal line, the third gate signal line being electrically connected to the gate of the third transistor; an orthographic projection of the third gate signal line on the substrate at least partially overlaps with an orthographic projection of the gate of the third transistor on the substrate.

9. The display panel according to claim 4, wherein the display panel further comprises a fourth conductive layer, the fourth conductive layer being located between the first conductive layer and the second type active layer;
the pixel circuit further comprises a first capacitor, the first capacitor comprising a first plate and a second plate disposed in a stacked manner, the first plate being located in the first conductive layer, the second plate being located in the fourth conductive layer, a second gate of the driving transistor being connected to the second plate, the first gate of the driving transistor being connected to a second electrode of the driving transistor via a fourth connection line;
the second gate of the driving transistor is located in the fourth conductive layer, the second plate is reused as the second gate of the driving transistor, an orthographic projection of the first plate on the substrate is located within a range of an orthographic projection of the second plate on the substrate;
the first gate of the driving transistor is located in the second conductive layer.

10. The display panel according to claim 8, wherein the display panel further comprises a power line and a fifth conductive layer, the fifth conductive layer is located on a side of the third conductive layer away from the substrate, and the power line is located in the fifth conductive layer;
a first electrode of the first transistor is connected to the power line via a sixth connection line, and a second electrode of the first transistor is connected to a first electrode of the driving transistor via a seventh connection line;
an orthographic projection of the third gate signal line on the substrate overlaps with an orthographic projection of the first active region on the substrate.

11. The display panel according to claim 8, wherein the second type active layer further comprises a fourth active region, the fourth active region comprises a first branch portion extending along a first direction, a second branch portion extending along a second direction, and a third branch portion extending along the first direction, a channel region of the driving transistor is located in the second branch portion, and an orthographic projection of the first gate of the driving transistor on the substrate at least overlaps with an orthographic projection of the second branch portion on the substrate; a first electrode of the third transistor is connected to the first electrode of the driving transistor via the third branch portion;
the third active region and the fourth active region are connected as an integral structure.

12. The display panel according to claim 11, wherein the pixel circuit further comprises a second capacitor, the second capacitor comprises a third electrode plate and a fourth electrode plate arranged in a stacked manner, the third electrode plate is located in the first conductive layer, the fourth electrode plate is located in the fourth conductive layer, and the fourth electrode plate is connected to the first electrode of the driving transistor via an eighth connection line;
an orthographic projection of the third electrode plate on the substrate is on a side of an orthographic projection of the first gate of the driving transistor on the substrate opposite to an orthographic projection of the third gate signal line on the substrate.

13. The display panel according to claim 12, wherein the pixel circuit further comprises a fourth transistor and a fifth transistor, the first type active layer further comprises a fifth active region, the second type active layer further comprises a sixth active region, a channel region of the fourth transistor is located in the sixth active region, and a channel region of the fifth transistor is located in the fifth active region;
the display panel further comprises a data line, a second initialization signal line, and a fifth conductive layer, the fifth conductive layer is located on a side of the third conductive layer away from the substrate, the data line is located in the fifth conductive layer, the second initialization signal line is located in the third conductive layer;
a first electrode of the fourth transistor is connected to the data line via a ninth connection line, a second electrode of the fourth transistor is connected to the third electrode plate via a tenth connection line;
a first electrode of the fifth transistor is connected to the second initialization signal line, and a second electrode of the fifth transistor is connected to the tenth connection line.

14. The display panel according to claim 13, wherein the display panel further comprises a fourth gate signal line and a fifth gate signal line, a channel region of the fourth transistor overlaps with an orthographic projection of the fifth gate signal line on the sixth active region, and a channel region of the fifth transistor overlaps with an orthographic projection of the fourth gate signal line on the fifth active region;
the display panel further comprises a second auxiliary signal line, the second auxiliary signal line is arranged in a different layer from the fourth gate signal line and the fifth gate signal line, and the fourth gate signal line is connected to the fifth gate signal line via the second auxiliary signal line;
the fourth gate signal line is located in the first conductive layer, the fifth gate signal line is located in the second conductive layer, the second auxiliary signal line is located in the third conductive layer, the fourth gate signal line is connected to the second auxiliary signal line via a first type of via hole, and the fifth gate signal line is connected to the second auxiliary signal line via a second type of via hole.

15. The display panel according to claim 12, wherein the pixel circuit further comprises a fourth transistor and a fifth transistor, the first type active layer further comprises a fifth active region, the second type active layer further comprises a sixth active region, a channel region of the fourth transistor is located in the fifth active region, and a channel region of the fifth transistor is located in the sixth active region;
the display panel further comprises a data line, a second initialization signal line, and a fifth conductive layer, the fifth conductive layer is located on a side of the third conductive layer away from the substrate, the data line is located in the fifth conductive layer, the second initialization signal line is located in the third conductive layer, a first electrode of the fourth transistor is connected to the data line via a ninth connection line, a second electrode of the fourth transistor is connected to the third electrode plate via a tenth connection line, a first electrode of the fifth transistor is connected to the second initialization signal line, and a second electrode of the fifth transistor is connected to the tenth connection line.

16. The display panel according to claim 15, wherein the display panel further comprises a fourth gate signal line and a fifth gate signal line, a channel region of the fourth transistor is located at an orthographic projection of the fourth gate signal line on the fifth active region, and a channel region of the fifth transistor is located at an orthographic projection of the fifth gate signal line on the sixth active region;
an orthographic projection of the fourth gate signal line on the substrate at least partially overlaps with an orthographic projection of the fifth gate signal line on the substrate; the fourth gate signal line and the fifth gate signal line transmit the same signal.

17. The display panel according to claim 16, wherein the display panel further comprises a second auxiliary signal line, the second auxiliary signal line is arranged in a different layer from the fourth gate signal line and the fifth gate signal line, and the fourth gate signal line is connected to the fifth gate signal line via the second auxiliary signal line;
the fourth gate signal line is located in the first conductive layer, the fifth gate signal line is located in the second conductive layer, the second auxiliary signal line is located in the third conductive layer, the fourth gate signal line is connected to the second auxiliary signal line via a first type of via hole, and the fifth gate signal line is connected to the second auxiliary signal line via a second type of via hole.

18. The display panel according to claim 2, wherein the display panel further comprises a power line, a data line, a first electrode line, and a first electrode layer, the power line, the data line, and the first electrode line all extend along a first direction;
the display panel further comprises a fourth conductive layer and a fifth conductive layer, the fourth conductive layer is located between the first conductive layer and the second type active layer, the fifth conductive layer is located on a side of the third conductive layer away from the substrate, the power line, the data line, and the first electrode line are located in the fifth conductive layer, and the first electrode layer is located on a side of the fifth conductive layer away from the substrate; an orthographic projection of the data line on the substrate is located on a side of an orthographic projection of the power line on the substrate away from an orthographic projection of a first gate of a driving transistor on the substrate;
the display panel comprises a plurality of pixel circuits, each of the pixel circuits comprises a plurality of transistors, an orthographic projection of the power line on the substrate at least covers an orthographic projection of channel regions of part of the transistors in each of the pixel circuit on the substrate;
an orthographic projection of the first electrode layer on the substrate at least covers an orthographic projection of channel regions of part of the transistors on the substrate.

19. The display panel according to claim 18, the display panel further comprises a plurality of spare signal lines, the spare signal lines are disposed in the fifth conductive layer and extend along the first direction;
along the second direction, the adjacent spare signal lines are spaced apart by M pixel circuits, where M is an integer satisfying 2≤M≤12; the first direction intersects the second direction.

20. A display device, comprising a display panel, the display panel comprising:
a substrate;
a first type active layer located on one side of the substrate;
a second type active layer located on a side of the first type active layer away from the substrate;
a first transistor, a channel region of the first transistor being located in the first type active layer;
a second transistor, a channel region of the second transistor being located in the second type active layer;
a first conductive layer located on a side of the first type active layer away from the substrate;
a second conductive layer located on a side of the second type active layer away from the substrate;
a gate signal line at least partially located in the first conductive layer and the second conductive layer, the gate signal line being configured to transmit a same gate signal to the first transistor and the second transistor.
